(19) United States
(12) Patent Application Publication
(10) Pub. No.: US 2025/0376621 A1
(43) Pub. Date: Dec. 11, 2025

(54) HALIDE PEROVSKITE NANOCRYSTAL PARTICLES, EMITTERS, MANUFACTURING METHOD THEREOF

(71) Applicant: Seoul National University R&DB Foundation, Seoul (KR)

(72) Inventors: Tae-Woo Lee, Seoul (KR); Kyung Yeon Jang, Seoul (KR)

(21) Appl. No.: 19/228,605

(22) Filed: Jun. 4, 2025

(30) Foreign Application Priority Data
Jun. 5, 2024 (KR) 10-2024-0074038

(51) Int. Cl. C09K 11/06; C09K 11/02; H10K 50/115

(52) U.S. Cl. CPC C09K 11/06; C09K 11/025; C09K 2211/1007; H10K 50/115

(57) ABSTRACT

The present invention relates to halide perovskite nanocrystal particles, emitters, and a method of manufacturing the same. The halide perovskite nanocrystal particles according to the present invention have improved emission characteristics such as emission intensity and photoluminescence quantum efficiency by removing surface defects and have improved electrical characteristics, and at the same time, damage and size increases of the nanocrystal are suppressed. In addition, the halide perovskite nanocrystal particle emitters according to the present invention have uniformly and widely dispersed nanocrystals, prevent a red shift, achieve excellent emission efficiency and color purity, and implement a deep blue emission spectrum. In addition, the method of manufacturing halide perovskite emitters according to the present invention can manufacture the above-described emitters.

### TECHNICAL FIELD

The present invention relates to halide perovskite nanocrystal particles, emitters, and a manufacturing method thereof, and more specifically, to halide perovskite nanocrystal particles having excellent electrical characteristics through surface treatment and ligand substitution, emitters capable of preventing a red shift by suppressing energy transfer and electronic coupling, and a manufacturing method thereof.

### DISCUSSION OF RELATED ART

In order to achieve high-purity natural colors, which are key requirements for next-generation 4K/8K displays and essential elements of the ultra-high definition (UHD) (4K) color standards (Rec.2020) established by the International Telecommunication Union (ITU), research is being actively conducted on various types of light-emitting diodes, including organic light-emitting diodes (OLEDs), inorganic quantum dot light-emitting diodes (QLEDs), and organic/inorganic perovskite light-emitting diodes (PeLEDs).

Specifically, light-emitting diodes for achieving high-purity natural colors must possess a spectrum close to the primary colors in the CIE 1931 color space required by Rec. 2020. This means that the light-emitting diodes must have a suitable emission wavelength and a narrow spectral full width at half maximum (FWHM). In particular, for blue, deep blue light that satisfies the standards of coordinates of (0.131, 0.046) in the CIE 1931 color space with a wavelength of 467 nm is required.

Meanwhile, following the development of inorganic quantum dots (QDs), organic/inorganic perovskites with a perovskite crystal structure are drawing attention as ideal emitters that may be commercialized because they emit light with high color purity and may be synthesized at low cost. In particular, as shown in Patent Document 1 (Korean Patent No. 10-2531001), the development of organic/inorganic perovskites capable of blue light emission is actively underway.

Specifically, there are two major methods that may be adopted to obtain blue emission through organic/inorganic perovskites. Specifically, there is a method using a mixed-halide perovskite formed by mixing bromine (Br—) and chlorine (Cl—) anions, or a method using the quantum confinement effect by producing a bromine-based perovskite smaller than the exciton Bohr diameter. Such perovskite crystal particles are defined as perovskite QDs. The exciton Bohr diameter is usually 7 nm or more and 20 nm or less. For example, the exciton Bohr diameter of CsPbBr3 is 7 nm and that of MAPbBr3 is 10 nm, and a crystal smaller than the exciton Bohr diameter is defined as a QD. When CsPbBr3 has a size of 1 to 7 nm, it becomes a QD. Here, QDs with a size of 1 to 7 nm primarily exhibit blue region light, and more specifically, QDs with a size between 3 to 5.5 nm can primarily exhibit deep blue region light.

At this time, QDs are limited to nanocrystals having a size smaller than the exciton Bohr diameter, and nanocrystals are defined as including all crystal particles having a size smaller or larger than the exciton Bohr diameter.

When the two above-described methods are considered from the functional perspective of light-emitting devices, the method of achieving the blue color required by Rec. 2020 using the mixed-halide perovskite has a problem in that the emission wavelength changes due to halide anion segregation. In addition, defects caused by chlorine anions may act as deep traps, leading to very low quantum efficiency.

On the other hand, the method using the above-described quantum confinement effect does not have a halide segregation effect because it uses a single-type bromine anion, and deep traps caused by chlorine anions are not generated. Therefore, it is considered desirable to utilize halide perovskite nanocrystals using the quantum confinement effect in order to achieve highly efficient and stable operation.

However, since halide perovskite nanocrystals using the quantum confinement effect are vulnerable to surface defect formation due to their high surface area-to-volume ratio, it is necessary to utilize surface-treated halide perovskite nanocrystals using the quantum confinement effect in order to achieve highly efficient and stable operation.

When surface treatment is conducted, the surface treatment of nanocrystals is performed using two major methods. The first method is to replace the existing long ligands such as oleic acid and oleylamine contained in the precursor with ligands having strong binding affinity during the synthesis stage and perform synthesis. The second method is to further add ligands for the purpose of surface treatment during the purification stage after synthesis and perform purification. However, in the case of nanocrystals, when ligands are replaced in the precursor during the synthesis stage, it is difficult to precisely control the particle size, and the emission efficiency is lowered due to surface defects that are generated during the subsequent purification stage. Therefore, in the case of nanocrystals that use the quantum confinement effect, surface treatment performed during the purification stage after synthesis is necessary.

Regarding surface treatment performed after synthesis, in a conventional technology, long ligands, such as di-dodecyl dimethyl ammonium bromide (DDAB) disclosed in Non-Patent Document 1 [Highly Efficient Perovskite-Quantum-Dot Light-Emitting Diodes by Surface Engineering, Advanced Materials 2016, 28, 8718-8725] and a mixture of sodium sulfide and oleylamine (S-OLA) (Korea Patent Publication No. 10-2610695), were used by dissolving them in nonpolar solvents for surface treatment, and high emission efficiency was achieved thereby. However, when a long ligand is used in a nanocrystal utilizing the quantum confinement effect, there was a problem that the efficiency of the light-emitting device decreased due to the high insulating properties of the ligands.

Therefore, in the case of a halide perovskite nanocrystal, it is considered desirable to treat its surface with molecules having a short alkyl chain or an aromatic ring. However, ligands having a short alkyl chain or an aromatic ring are generally used by dissolving them in polar solvents such as 1-butanol in Non-Patent Document 2 [Electron-donating functional groups strengthen ligand-induced chiral imprinting on CsPbBr3 quantum dots, Scientific Reports 2024, 14, 336] and N,N-dimethylformamide in Non-Patent Document 3 [Bipolar-shell resurfacing for blue LEDs based on strongly confined perovskite quantum dots, Nature Nanotechnology 2020, 15, 668-674] due to their limited solubility. However, these polar solvents have limitations because they may damage the halide perovskite nanocrystal or change its size. Therefore, a technology is required to surface-treat a halide perovskite nanocrystal with short ligands without using polar solvents and without damaging the nanocrystal.

Meanwhile, in terms of color purity, a halide perovskite nanocrystal exhibits lower color purity than mixed-halide perovskites. This is because the method of utilizing the quantum confinement effect offers emission that depends on the quantum size. Specifically, as the size of the nanocrystal decreases, the quantum size dependence of the emission spectrum increases, while it becomes difficult to control the nanocrystal size uniformly.

Therefore, even when the emitted light has a wavelength of 467 nm corresponding to the blue primary color in Rec. 2020, it shows a coordinate point far from the blue primary color coordinate of Rec. 2020 in the CIE 1931 color space due to the wide FWHM. This means that the color purity is reduced.

To overcome this problem, a more blue-shifted spectrum is required at 467 nm. However, smaller perovskite nanocrystals, when formed into a thin film to be used as a light-emitting layer of an LED, exhibit a red shift in their emission spectrum, unlike those dispersed in a solution. Specifically, this is because, unlike inorganic nanocrystals with a core-shell structure, perovskite nanocrystals composed of only a core have a short distance between nanocrystals, so energy transfer and electronic coupling between nanocrystals occur strongly.

At this time, in order to form a halide perovskite nanocrystal and form emitters of an LED with them, a solution process such as spin coating is used because the grain size may not be controlled to the nanocrystal level by the deposition process.

Therefore, in order to obtain an emission spectrum at a wavelength of 467 nm less in an organic/inorganic halide perovskite LED using halide perovskite nanocrystals, it is necessary to prevent energy transfer and electronic coupling between nanocrystals.

Recently, LEDs utilizing a halide perovskite nanocrystal have been reported to have an emission spectrum peak at 469 nm to 480 nm (ACS Energy Lett.2023, 8, 731-739, Adv. Mater. 2021, 33, 2006722, Nat. Nanotech. 2020, 15, 668-674), but they fail to satisfy the color standards of Rec.2020.

### RELATED ART DOCUMENTS

### Patent Documents

(Patent Document 1) Korea Patent Publication No. 10-2531001

(Patent Document 2) Korea Patent Publication No. 10-2610695

### Non-Patent Documents

(Non-Patent Document 1) [Highly Efficient Perovskite-Quantum-Dot Light-Emitting Diodes by Surface Engineering, Advanced Materials 2016, 28, 8718-8725)]

(Non-Patent Document 2) [Electron-donating functional groups strengthen ligand-induced chiral imprinting on CsPbBr3 quantum dots, Scientific Reports 2024, 14, 336]

(Non-Patent Document 3) [Bipolar-shell resurfacing for blue LEDs based on strongly confined perovskite quantum dots, Nature Nanotechnology 2020, 15, 668-674]

(Non-Patent Document 4) [Perovskite Quantum Dots with Ultralow Trap Density by Acid Etching-Driven Ligand Exchange for High Luminance and Stable Pure-Blue Light-Emitting Diodes, Advanced Materials 2021, 33, 2006722]

(Non-Patent Document 5) [Benzoyl Halides as Alternative Precursors for the Colloidal Synthesis of Lead-Based Halide Perovskite Nanocrystals, Journal of the American Chemical Society 2018, 140, 7, 2656-2664]

(Non-Patent Document 6) [Efficient Zn2+ doping into CsBr nanocrystals using benzoyl bromide, Journal of Photochemistry & Photobiology, A: Chemistry 442 (2023) 114760]

### SUMMARY OF THE INVENTION

### Problem to be Solved

The first objective of the present invention is to provide halide perovskite nanocrystal particles which improve light emission characteristics by removing the surface defects of halide perovskite nanocrystals, improve the electrical characteristics by replacing long ligands with short ligands, suppress damage and size increases of nanocrystals, have higher emission intensity and photoluminescence quantum efficiency compared to halide perovskite nanocrystal particles that are not treated with acyl halides, and exhibit high external quantum efficiency when used in light-emitting devices.

The second objective of the present invention is to provide halide perovskite nanocrystal particle emitters in which nanocrystals are uniformly and widely dispersed, energy transfer and electronic coupling between nanocrystals are suppressed to prevent a red shift, halide segregation and deep traps do not occur, energy can be transferred to halide perovskite nanocrystals through an organic host having semiconductor properties, excellent emission efficiency and color purity can be achieved, and a deep blue emission spectrum can be implemented.

The third objective of the present invention is to provide a halide perovskite nanocrystal particle emitter manufacturing method capable of manufacturing the above-described emitters.

The fourth objective of the present invention is to provide a light-emitting device that can improve the external quantum efficiency of a light-emitting device by balancing charges through an organic host having semiconductor properties, exhibit excellent emission efficiency, and emit deep blue light.

### Means for Solving the Problem

In order to achieve the first objective described above, there are provided halide perovskite nanocrystal particles in which an acyl halide of the following Chemical Formula 1 is bonded to the surface of the perovskite nanocrystal.

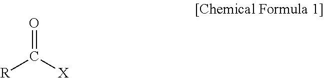

In Chemical Formula 1, X is a halogen element corresponding to F, Cl, Br, or I, and R is a substituted or unsubstituted aromatic ring or a substituted or unsubstituted hydrocarbon group.

In addition, the above-described perovskite nanocrystal may be surrounded by an organic or inorganic ligand.

In addition, the acyl halide of Chemical Formula 1 may be acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, 2-chloropropionyl chloride, acetyl iodide, propionyl iodide, valeryl iodide, benzoyl iodide, bromoacetyl iodide, 2-bromopropionyl iodide, or 2-bromobutyryl iodide, but is not limited thereto.

In addition, the above-described halide perovskite nanocrystal may include an ABX3 crystal. At this time, A is a monovalent organic cation, a monovalent inorganic cation, or a combination thereof, B is a divalent metal ion, and X is F—, Cl—, Br—, I—, SCN—, OCN—, SeCN—, HCO2—, CH3COO—, or a combination thereof.

In addition, the size of the above-described halide perovskite nanocrystal may range from 1nm to 10 um. For example, it may be 1 nm, 1.5 nm, 2 nm, 2.5 nm, 3 nm, 3.5 nm, 4 nm, 4.5 nm, 5 nm, 5.5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. Preferably, it is 3 nm or more and 30 nm or less.

In addition, the size of the above-described halide perovskite nanocrystal may be 3 to 5.5 nm, and the above-described halide perovskite nanocrystal may have an emission spectrum peak at a wavelength of 440 to 470 nm. For example, the size of the above-described halide perovskite nanocrystal may be 3.0 nm, 3.1 nm, 3.2 nm, 3.3 nm, 3.4 nm, 3.5 nm, 3.6 nm, 3.7 nm, 3.8 nm, 3.9 nm, 4.0 nm, 4.1 nm, 4.2 nm, 4.3 nm, 4.4 nm, 4.5 nm, 4.6 nm, 4.7 nm, 4.8 nm, 4.9 nm, 5.0 nm, 5.1 nm, 5.2 nm, 5.3 nm, 5.4 nm, or 5.5 nm. Preferably, it may be 3.5 to 4.5 nm to exhibit a deep blue color.

In addition, the size of the halide perovskite nanocrystal particles emitting blue light without including chloride anion (Cl—) in the above-described halide perovskite nanocrystals may range from 3 nm to 5.5 nm. For example, it may be 3.0 nm, 3.1 nm, 3.2 nm, 3.3 nm, 3.4 nm, 3.5 nm, 3.6 nm, 3.7 nm, 3.8 nm, 3.9 nm, 4.0 nm, 4.1 nm, 4.2 nm, 4.3 nm, 4.4 nm, 4.5 nm, 4.6 nm, 4.7 nm, 4.8 nm, 4.9 nm, 5.0 nm, 5.1 nm, 5.2 nm, 5.3 nm, 5.4 nm, or 5.5 nm. Preferably, it may be 3.5 to 4.5 nm to exhibit a deep blue color.

In order to achieve the second objective described above, there are provided halide perovskite nanocrystal particle emitters including the above-described halide perovskite nanocrystal particles and an organic host.

In addition, the above-described organic host may prevent a red shift by suppressing energy transfer and electronic coupling between halide perovskite nanocrystals.

In addition, the above-described organic host may have a highest occupied molecular orbital (HOMO) energy level of −6.0 eV or less. Preferably, a combination that does not form an exciplex with an adjacent charge transport layer may be used so that the HOMO energy level is −6.0 eV or less.

In addition, the above-described organic host may be a carbazole derivative.

In addition, the above-described organic host may be selected from the group consisting of Chemical Formulas 2 to 4.

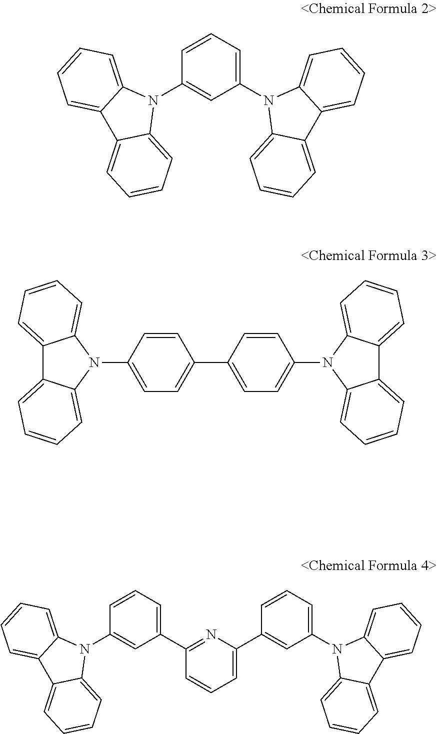 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

In addition, 1 to 60 parts by weight of the above-described nanocrystal may be mixed based on 100 parts by weight of the above-described organic host. Preferably, 5 to 30 parts by weight may be mixed. More preferably, 10 to 20 parts by weight may be mixed. More specifically, it may include a range in which the lower value of two numbers among 1, 2, 3, 4, 5, 6, 7, 8, 9, 10, 10.5, 11, 11.5, 12, 12.5, 13, 13.5, 14, 14.5, 15, 15.5, 16, 16.5, 17, 17.5, 18, 18.5, 19, 19.5, 20, 25, 30, 35, 40, 45, 50, 55, and 60 parts by weight is a lower limit and the higher value is an upper limit.

In addition, the size of the above-described halide perovskite nanocrystal may be 3 to 5.5 nm. For example, it may be 3.0 nm, 3.1 nm, 3.2 nm, 3.3 nm, 3.4 nm, 3.5 nm, 3.6 nm, 3.7 nm, 3.8 nm, 3.9 nm, 4.0 nm, 4.1 nm, 4.2 nm, 4.3 nm, 4.4 nm, 4.5 nm, 4.6 nm, 4.7 nm, 4.8 nm, 4.9 nm, 5.0 nm, 5.1 nm, 5.2 nm, 5.3 nm, 5.4 nm, or 5.5 nm. Preferably, it may be 3.5 to 4.5 nm.

In addition, the above-described halide perovskite nanocrystal may have an organic ligand, an inorganic ligand, and an acyl halide ligand bound to the surface of the nanocrystal.

According to one embodiment of the present invention, the average distance between the above-described halide perovskite nanocrystal particles may be 4 to 12 nm. Preferably, it may be 7 to 10 nm. More specifically, it may include a range in which the lower value of two numbers among 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, and 12 nm is a lower limit and the higher value is an upper limit.

According to one embodiment of the present invention, the above-described halide perovskite nanocrystal particle emitters may have an emission spectrum peak at a wavelength of 420 to 467 nm. Preferably, it may have an emission spectrum peak at 440 to 467 nm, and more specifically, a range in which the lower value of two numbers among 420 nm, 425 nm, 430 nm, 435 nm, 440 nm, 445 nm, 450 nm, 455 nm, 457 nm, 459 nm, 461 nm, 463 nm, 465 nm, and 467 nm is a lower limit and the higher value is an upper limit may be included.

In order to achieve the third objective described above, there is provided method of manufacturing halide perovskite nanocrystal particle emitters, the method including: preparing a halide perovskite nanocrystal particle solution or thin film; and performing surface treatment or ligand substitution on a halide perovskite nanocrystal using an additive solution containing an acyl halide represented by Chemical Formula 1 below in the halide perovskite nanocrystal particle solution or thin film:

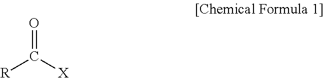

In Chemical Formula 1, X is a halogen element corresponding to F, Cl, Br, or I, and R is a substituted or unsubstituted aromatic ring or a substituted or unsubstituted hydrocarbon group.

In addition, the above-described perovskite nanocrystal may be surrounded by an organic or inorganic ligand.

In addition, the acyl halide of Chemical Formula 1 may be selected from the group consisting of acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, 2-chloropropionyl chloride, acetyl iodide, propionyl iodide, valeryl iodide, benzoyl iodide, bromoacetyl iodide, 2-bromopropionyl iodide, and 2-bromobutyryl iodide.

In addition, the above-described additive solution may further include a ligand.

In addition, the above-described ligand may be selected from the group consisting of aniline, benzylamine, phenethylamine, 3-phenyl-1-propylamine, 4-phenylbutylamine, ethylamine, propylamine, butylamine, pentylamine, isobutylamine, and isopropylamine.

In addition, the additive solution may be a solution containing 0.01 to 50 parts by weight of acyl halide and a ligand based on 100 parts by weight of a nonpolar solvent.

In addition, a solvent that is used when preparing the above-described additive solution may include any one of toluene, xylene, chlorobenzene, chloroform, tetrahydrofuran, cyclohexanone, and a combination thereof.

In addition, the method may further include additionally forming a passivation layer on an upper portion or lower portion of the thin film using the additive solution containing the acyl halide. In addition, the above-described perovskite nanocrystal particle emitters may further include an organic host.

In addition, the above-described organic host may have a HOMO energy level of −6.0 eV or less.

In addition, the above-described organic host may be a carbazole derivative.

In addition, the above-described organic host may be selected from the group consisting of Chemical Formulas 2 to 4.

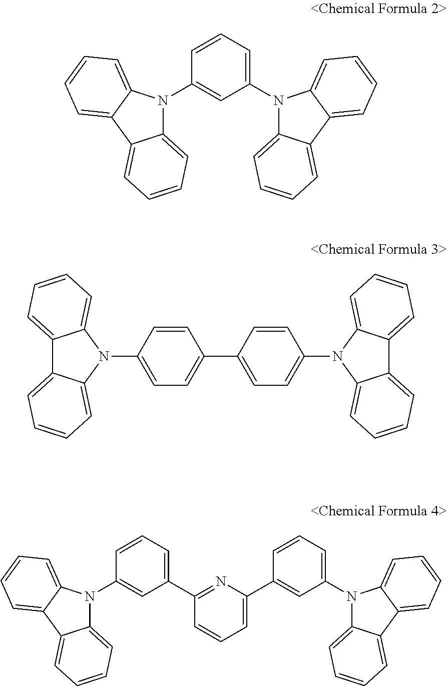 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

In addition, 1 to 60 parts by weight of the nanocrystal may be mixed based on 100 parts by weight of the organic host.

In order to achieve the third objective described above, there is provided a method of preparing a halide perovskite nanocrystal particle coating solution, the method including: a step of preparing a first solution containing the halide perovskite nanocrystal; and a second step of mixing a second solution containing an organic host for suppressing energy transfer and electronic coupling between the first solution and the halide perovskite nanocrystal.

In addition, the step of preparing the first solution containing the halide perovskite nanocrystal includes: a step of preparing an additive solution for surface treatment or ligand substitution of the halide perovskite nanocrystal; and a step of preparing surface-treated and ligand-substituted halide perovskite nanocrystal particles using the additive solution.

At this time, the acyl halide of Chemical Formula 1 included in the additive solution may be acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, or 2-chloropropionyl chloride.

In addition, the ligand included in the additive solution may be aniline, benzylamine, phenethylamine, 3-phenyl-1-propylamine, 4-phenylbutylamine, ethylamine, propylamine, butylamine, pentylamine, isobutylamine, or isopropylamine.

In addition, the additive solution is a solution containing 0.01 to 50 parts by weight of acyl halide and a ligand based on 100 parts by weight of a nonpolar solvent.

In addition, there is provided a method of manufacturing the above-described halide perovskite nanocrystal particle emitters, the method including: a step of manufacturing emitters by applying the above-described halide perovskite nanocrystal particle emitter coating solution.

In order to achieve the fourth objective described above, there is provided a perovskite light-emitting device selected from the group consisting of a light-emitting diode, a light-emitting transistor, a laser-emitting device, and a polarized light-emitting device including the above-described halide perovskite nanocrystal particles or the above-described halide perovskite nanocrystal particle emitters.

Meanwhile, it is disclosed that the present invention was invented with the support of the following national research and development projects.
[National research and development program supporting the present invention 1]
[Project identification number] 2400422598 [Project number] RS-2024-00422598
[Name of relevant ministry] Ministry of Science and ICT [Project management (specialized) agency name] Commercialization Promotion Agency for R&D Outcome

[Research program name] University Technology Management Promotion (1P Star Scientist, Support type)
[Research project name] IP advancement and commercialization for commercialization of next-generation electronic materials and electronic device technology using optical and electrical characteristics of perovskite
[Contribution rate] 50/100 [Project performing agency name] Seoul National University Tech-biz Innovation Platform
[Research period] April 1, 2024 to Dec. 31, 2025

### Effects of the Invention

The halide perovskite nanocrystal particles according to the present invention can improve light emission characteristics by removing the surface defects of halide perovskite nanocrystals, improve the electrical characteristics by replacing long ligands with short ligands, suppress damage and size increases of the nanocrystals, have higher emission intensity and photoluminescence quantum efficiency compared to halide perovskite nanocrystal particles that are not treated with acyl halides, and exhibit high external quantum efficiency when used in light-emitting devices.

In addition, in the halide perovskite nanocrystal particle emitters according to the present invention, nanocrystals are uniformly and widely dispersed, energy transfer and electronic coupling between nanocrystals are suppressed to prevent a red shift, halide segregation and deep traps do not occur, energy can be transferred to halide perovskite nanocrystals through an organic host having semiconductor properties, excellent emission efficiency and color purity can be achieved, and a deep blue emission spectrum can be implemented.

In addition, the halide perovskite emitter manufacturing method according to the present invention is capable of manufacturing the above-described emitters.

Furthermore, the light-emitting device according to the present invention can improve the external quantum efficiency of a light-emitting device by balancing charges through an organic host having semiconductor properties, exhibit excellent emission efficiency, and emit deep blue light.

### BRIEF DESCRIPTION OF THE DRAWINGS

FIG. 1 shows a schematic diagram illustrating a process of synthesizing a halide perovskite nanocrystal using a hot-injection method according to a preferred embodiment of the present invention.

FIG. 2A shows a schematic diagram illustrating a surface-treated halide perovskite nanocrystal according to a preferred embodiment of the present invention.

FIG. 2B shows a schematic diagram illustrating a surface treatment process of the halide perovskite nanocrystal according to a preferred embodiment of the present invention.

FIG. 3 shows a reaction scheme illustrating a surface treatment mechanism of benzoyl bromide used in the surface treatment process of the halide perovskite nanocrystal.

FIG. 4 shows a schematic diagram illustrating a process of manufacturing emitters including an organic host (1,3-di-9-carbazolylbenzene, mCP) and the halide perovskite nanocrystal according to a preferred embodiment of the present invention.

FIG. 5 shows a schematic diagram illustrating the structure of a halide perovskite light-emitting device including emitters including the organic host (mCP) and the halide perovskite nanocrystal according to a preferred embodiment of the present invention.

FIG. 6 shows an image of a halide perovskite nanocrystal according to a preferred embodiment of the present invention observed using a transmission electron microscope (TEM).

FIG. 7A shows a graph illustrating an emission spectrum of a halide perovskite nanocrystal before/after surface treatment. In addition, FIG. 7B shows a graph illustrating the photoluminescence quantum efficiency of a halide perovskite nanocrystal before/after surface treatment. Furthermore, FIG. 7C shows a graph illustrating a Fourier transform infrared spectrum of a halide perovskite surface ligand before/after surface treatment.

FIG. 8 shows a graph illustrating an absorption region and an emission region of a CsPbBr3 halide perovskite nanocrystal according to a preferred embodiment of the present invention.

FIG. 9 shows a schematic diagram illustrating the electronic coupling of a CsPbBr3 halide perovskite nanocrystal according to a preferred embodiment of the present invention.

FIG. 10 shows a schematic diagram illustrating the structure of emitters (mCP:QD) including an organic host (mCP) and a halide perovskite nanocrystal according to a preferred embodiment of the present invention and emitters (QD) including a halide perovskite nanocrystal but not including an organic host.

FIG. 11A shows a graph illustrating emission spectra of emitters (mCP:QD) including an organic host (mCP) and a halide perovskite nanocrystal according to a preferred embodiment of the present invention, according to the photoluminescence lifetime range.

FIG. 11B shows a graph illustrating emission spectra of emitters (QD) including a halide perovskite nanocrystal but not including an organic host, according to the photoluminescence lifetime range.

FIG. 11C shows graphs illustrating emission spectra of emitters including an organic host other than mCP (4,4′-bis(N-carbazolyl)-1,1′-biphenyl (CBP), 2,6-bis[3′(N-carbazolyl)phenyl]pyridine (DCzPPy), 4,4′,4″-tris(carbazol-9-yl)triphenylamine (TCTA)) and a halide perovskite nanocrystal.

FIG. 12A shows a graph illustrating a spectrum peak according to the average distance between halide perovskite nanocrystals.

FIG. 12B shows emission spectra of emitters representing three points (a, b, c) marked in the graph of FIG. 12A.

FIG. 12C shows a Tauc plot graph based on the absorption spectrum of emitters representing the three points (a, b, c) marked in the graph of FIG. 12A.

FIG. 12D, FIG. 12E, and FIG. 12F are time-resolved spectrum maps at three points (a, b, c) marked in the graph of FIG. 12A and graphs of spectrum peaks extracted therefrom.

FIG. 13A shows a graph illustrating an emission spectrum of an organic host (mCP) according to a preferred embodiment of the present invention and an absorption spectrum and an emission spectrum of a halide perovskite nanocrystal.

FIG. 13B shows a graph illustrating an emission spectrum of an organic host (mCP) according to an excitation spectrum (excitation wavelength) according to a preferred embodiment of the present invention.

FIG. 13C shows a graph illustrating an emission spectrum of emitters (mCP:QD) including an organic host (mCP) and a halide perovskite nanocrystal according to an excitation spectrum according to a preferred embodiment of the present invention.

FIG. 13D shows a graph illustrating an emission spectrum of emitters (QD) including a halide perovskite nanocrystal but not including an organic host according to an excitation spectrum.

FIGS. 14A and 14B show graphs obtained from a transient section of an emission spectrum of light emitted from emitters from a signal applied by a pulse generator that excites an emitter. FIG. 14A shows a transient emission graph of a halide perovskite nanocrystal according to the presence or absence of an organic host, and FIG. 14B shows a transient emission graph of an organic host according to the presence or absence of a halide perovskite nanocrystal. FIGS. 15A-15C show graphs obtained from a transient section of an electroluminescence spectrum of light emitted from a light-emitting device from a signal applied by a pulse generator that drives a halide perovskite light-emitting device. FIG. 15A shows a graph of the entire section, FIG. 15B shows a graph illustrating a section where the intensity of electroluminescence increases from the signal application, and FIG. 15C shows a graph illustrating a section where the intensity of electroluminescence decreases after the signal application stops.

FIG. 16A shows a current density-voltage graph of a halide perovskite light-emitting device including an organic host (mCP) and a halide perovskite nanocrystal and a halide perovskite light-emitting device not including an organic host but including a halide perovskite nanocrystal.

FIG. 16B shows a luminance-current density graph of the halide perovskite light-emitting device including an organic host (mCP) and a halide perovskite nanocrystal and the halide perovskite light-emitting device not including an organic host but including a halide perovskite nanocrystal.

FIG. 16C shows an external quantum efficiency-voltage graph of the halide perovskite light-emitting device including an organic host (mCP) and a halide perovskite nanocrystal and the halide perovskite light-emitting device not including an organic host but including a halide perovskite nanocrystal.

FIG. 16D shows a graph illustrating electroluminescence spectra of the halide perovskite light-emitting device including an organic host (mCP) and a halide perovskite nanocrystal and the halide perovskite light-emitting device not including an organic host but including a halide perovskite nanocrystal.

FIG. 16E shows a graph illustrating color positions of the electroluminescence spectra of the halide perovskite light-emitting device including an organic host (mCP) and a halide perovskite nanocrystal and the halide perovskite light-emitting device not including an organic host but including a halide perovskite nanocrystal, on the CIE 1931 chromaticity diagram.

### DETAILED DESCRIPTION OF EMBODIMENTS

Hereinafter, with reference to the attached drawings, embodiments of the present invention will be described in detail so that those with ordinary skill in the art to which the present invention pertains may easily implement the present invention. The present invention may be implemented in various different forms and is not limited to the embodiments described herein. In the drawings, parts that are not related to the description are omitted in order to clearly describe the present invention.

The terminology used in the present invention is for the purpose of describing particular embodiments only and is not intended to limit the present invention. Singular forms include plural forms, unless the context clearly indicates otherwise. In the present invention, terms such as “comprise” or “have” are intended to specify the presence of features, numbers, steps, operations, components, or combinations thereof described herein, and should not be understood as precluding the possibility of the presence or addition of one or more other features, numbers, steps, operations, components, or combinations thereof.

Unless otherwise defined, all terms, including technical and scientific terms used herein, have the same meaning as generally understood by one of ordinary skill in the art to which the present invention pertains. Terms, such as those defined in commonly used dictionaries, should be interpreted as having a meaning that is consistent with their meaning in the context of the relevant art and are not interpreted in an idealized or overly formal sense unless explicitly defined in the present invention.

The term “halide perovskite” as used herein includes a pseudo-halide perovskite.

The term “emitter” as used herein refers to an emitter including a single compound or a mixture and includes an emission layer.

As described above, in order to manufacture a high-efficiency blue light-emitting device using halide perovskite nanocrystal particles, it is preferable to control defects by surface treatment and to replace the existing oleic acid and oleylamine with a ligand having a short carbon chain or an aromatic ring. However, the conventional techniques for surface treatment and ligand substitution of halide perovskite nanocrystal particles use a ligand having a long alkyl side chain or use a polar solvent, and therefore, there is the problem of making it difficult to control the size of the nanocrystal.

Accordingly, the present invention seeks to solve the above-described problem by providing halide perovskite nanocrystal particles in which an acyl halide of Chemical Formula 1 below is bonded to the surface of the perovskite nanocrystal. Through this, it is possible to exhibit high photoluminescence quantum efficiency and achieve substitution with an aromatic ring or short carbon chain ligand, while maintaining the size of the nanocrystal in the quantum dot range.

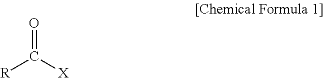

(In Chemical Formula 1, X is a halogen element corresponding to F, Cl, Br, or I, and R is a substituted or unsubstituted aromatic ring or a substituted or unsubstituted hydrocarbon group.)

Meanwhile, as described above, in order to obtain blue emission using emitters using halide perovskite nanocrystal particles, small-sized nanocrystal particles are required. However, as the size of the nanocrystal particles decreases, it becomes difficult to uniformly control the size of the nanocrystal particles, and accordingly, the spectrum of the nanocrystal particles has a wide full width at half maximum (FWHM). To overcome this, a spectrum that is further blue-shifted at 467 nm, which is a wavelength corresponding to blue, is required.

In addition, since the grain size of the halide perovskite nanocrystal particles may not be controlled to the nanocrystal level through a deposition process, light-emitting diode (LED) emitters may not be formed through a deposition process and must be formed through a solution process. However, when a coating solution for emitters is prepared with halide perovskite nanocrystal particles and then emitters are manufactured using the coating solution, unlike in the coating solution state, the average distance between nanocrystal particles becomes closer in the emitters formed into a thin film, causing energy transfer and electronic coupling between nanocrystals, which causes a problem in that the emission spectrum is red-shifted.

Accordingly, the present invention seeks to solve the above-described problem by providing emitters including halide perovskite nanocrystal particles and an organic host for suppressing energy transfer and electronic coupling between the halide perovskite nanocrystals, and a manufacturing method thereof. Through this, when emitters are formed using the above-described coating solution, the nanocrystals can be uniformly dispersed, energy transfer and electronic coupling between nanocrystals in the emitters can be suppressed to prevent a red shift, a deep blue emission spectrum can be implemented, and high emission efficiency can be achieved.

First, halide perovskite nanocrystal particles are described.

Halide perovskites include not only perovskites with only halides but also pseudo-halide perovskites. Pseudo-halide perovskites mean that the halide site is replaced by another element, and the other element is not limited as long as it may form pseudo-halide perovskites. A halide perovskite nanocrystal refers to a nanocrystal including a halide perovskite crystal. The above-described halide perovskite crystal may be used without limitation as long as it may typically form emitters. Preferably, an acyl halide of Chemical Formula 1 below may be bonded to the surface of the above-described perovskite nanocrystal. More preferably, the above-described halide perovskite nanocrystal is a nanocrystal particle in which an acyl halide ligand of Chemical Formula 1 below is additionally bonded to the surface while the nanocrystal is surrounded by an organic or inorganic ligand.

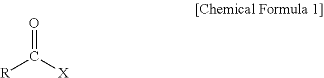

In Chemical Formula 1, X is a halogen element corresponding to F, Cl, Br, or I, and R is a substituted or unsubstituted aromatic ring or a substituted or unsubstituted hydrocarbon group.

The above-described acyl halide of Chemical Formula 1 may be acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, 2-chloropropionyl chloride, acetyl iodide, propionyl iodide, valeryl iodide, benzoyl iodide, bromoacetyl iodide, 2-bromopropionyl iodide, or 2-bromobutyryl iodide, but is not limited thereto.

An acyl halide ligand can react with other amine and acid ligands constituting the halide perovskite nanocrystals to provide bromine anions to the halide perovskite nanocrystals, thereby removing surface defects. At the same time, the acyl halide ligand can be bound as a ligand to replace oleic acid and oleylamine, which have long alkyl side chains that are previously bound to the perovskite surface. Ultimately, the acyl halide ligand can increase the emission intensity and photoluminescence quantum efficiency of halide perovskite nanocrystals while improving electrical characteristics.

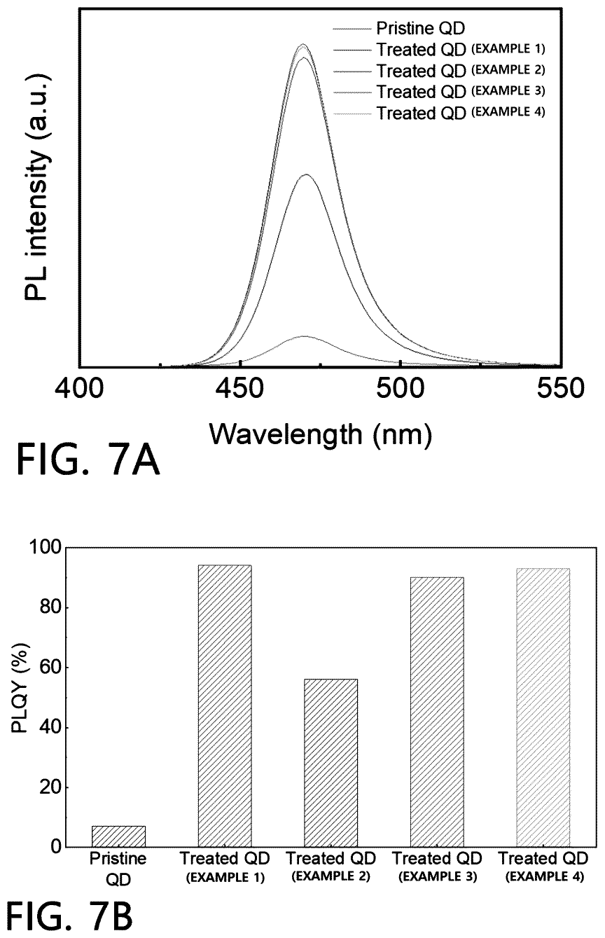

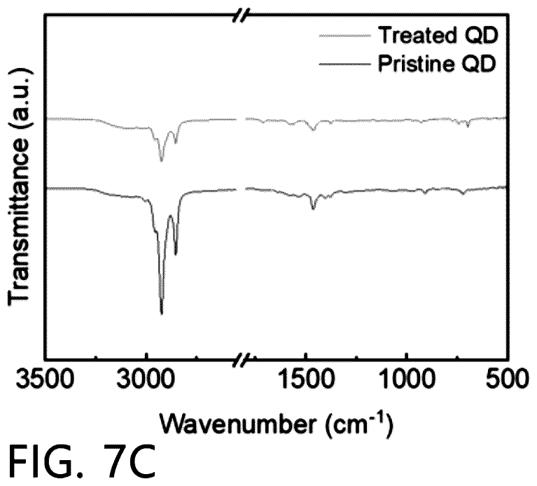

This may be confirmed through FIGS. 7A, 7B, and 7C. Specifically, referring to FIG. 7A, it can be seen that the emission intensity of the surface-treated nanocrystal is stronger than that of the non-surface-treated nanocrystal. Referring to FIG. 7B, it can be seen that the photoluminescence quantum efficiency of the surface-treated nanocrystal is superior to that of the non-surface-treated nanocrystal. Referring to FIG. 7C, it can be seen that the alkyl group component is reduced in the surface-treated nanocrystal compared to the non-surface-treated nanocrystal. In addition, referring to FIG. 7C, the characteristic peak of the carbonyl group that is present in the acyl halide appears, and therefore, it can be confirmed that the acyl halide is bonded to the surface of the halide perovskite nanocrystal as a ligand.

Compared with previous related art documents, as shown in Table 1 below, the research article published in Advanced Materials 2016, 28, 8718-8725, the research article published in Advanced Materials 2021, 33, 2006722, and the Korea Patent Publication No. 10-2531001 show that the perovskite surface is composed of a ligand having an alkyl side chain with eight or more carbon atoms. According to the research article published in Nature Nanotechnology, 2020, 15, 668-674, the organic ligand was removed and replaced with an inorganic ligand but the size of the halide perovskite nanocrystal was not controlled, and therefore, there is a limitation that the main excitonic peak appeared at 460 nm or higher. In the present invention, the surface is composed of a ligand having seven or fewer carbon atoms or including an aromatic ring, thereby improving electrical characteristics while maintaining high photoluminescence quantum efficiency and an excitonic peak of 455 nm or less suitable for blue light. Table 1 below shows the ligand composition, photoluminescence quantum efficiency, and excitonic peak of halide perovskite nanocrystal particles of the present invention and related art literature.

TABLE 1

| | | | Excitonic |
|---|---|---|---|
| | | Photoluminescence | absorption |
| Source | Ligand composition | quantum efficiency | peak |
| Advanced Materials | Didodecyldimethylammonium bromide | 71% | >510 nm |
| 2016, 28, 8718-8725 | | | |
| | 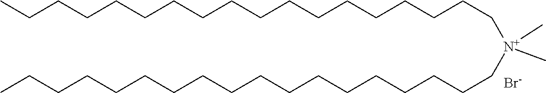 [SMILES: CCCCCCCCCCCCCCCCCC[N+](C)(C)CCCCCCCCCCCCCCCCCC ; [Br-]] | | |
| Advanced Materials | Didodecylamine | 97% | <455 nm |
| 2021, 33, 2006722 | | | |
| | 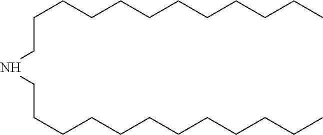 [SMILES: CCCCCCCCCCCCNCCCCCCCCCCCC] | | |
| | Phenethylamine | | |
| | 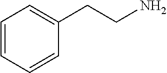 | | |
| Nature | Sodium bromide | >90% | >460 nm |
| Nanotechnology, | (NaBr) | | |
| 2020, 15, 668-674 | | | |
| Korea Patent | S(sulfide)-oleylamine/dodecylamine/ | — | >670 nm |
| Publication No. | octylamine | | |
| 10-2531001 | | | |
| | 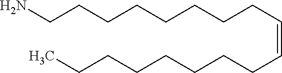 [SMILES: CCCCCCCC/C=C\CCCCCCCCN] | | |
| Present invention | Benzoyl bromide | >90% | <455 nm |
| | 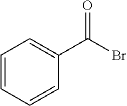 | | |
| | Phenethylamine | | |
| | 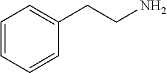 | | |
| Present invention | Acetyl bromide | >90% | <455 nm |
| | 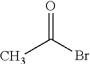 | | |
| | Aniline | | |
| | 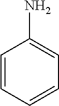 | | |

In addition, Table 2 below compares the structures of alkyl halides and acyl halides. Referring to this, when compared to the related art document Korea Patent Publication No. 10-2020-0074697 that uses alkyl halide as a ligand, since the acyl halide has an additional oxygen element in the bonding portion, the unshared electron pair of the oxygen atom may provide an additional electron pair to the surface of the halide perovskite nanocrystal and form a strong interaction.

TABLE 2

| Korea Patent Publication No. | Present |
|---|---|
| 10-2020-0074697 | invention |
| R—X Alkyl halide | 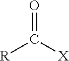 |
| | Acyl halide |

Meanwhile, according to the present invention, R in Chemical Formula 1 is a substituted or unsubstituted aromatic ring or a substituted or unsubstituted hydrocarbon group. Preferably, R may be an aromatic ring or a C1-20 alkyl group, more preferably, R may be an aromatic ring or a C1-20 alkyl group, and even more preferably, R may be an aromatic ring or a C1-7 alkyl group.

First, in R in Chemical Formula 1, the aromatic ring refers to an organic compound having a benzene ring in the molecule, which is a derivative of benzene.

The hydrocarbon group in Chemical Formula 1 may be, for example, an alkyl group, an alkylene group, a cycloalkyl group, or an aromatic group such as benzene. The hydrocarbon group may be, for example, a hydrocarbon group having 1 to 100 carbon atoms, 1 to 25 carbon atoms, 1 to 10 carbon atoms, or 1 to 6 carbon atoms.

In addition, in the expression “substituted or unsubstituted” of R in Chemical Formula 1 according to the present invention, “substitution” means that one or more hydrogen atoms in the hydrocarbon are each, independently of one another, substituted with the same or different substituents. Useful substituents include the following, but are not limited thereto.

Such a substituent may be one or more selected from the group consisting of —F; —Cl; —Br; —CN; —NO2; —OH; a C1-C20 alkyl group unsubstituted or substituted with —F, —Cl, —Br, —CN, —NO2, or —OH; a C1-C20 alkoxy group unsubstituted or substituted with —F, —Cl, —Br, —CN, —NO2, or —OH; a C6-C30 aryl group unsubstituted or substituted with a C1-C20 alkyl group, a C1-C20 alkoxy group, —F, —Cl, —Br, —CN, —NO2, or —OH; a C6-C30 heteroaryl group unsubstituted or substituted with a C1-C20 alkyl group, a C1-C20 alkoxy group, —F, —Cl, —Br, —CN, —NO2, or —OH; a C5-C20 cycloalkyl group unsubstituted or substituted with a C1-C20 alkyl group, a C1-C20 alkoxy group, —F, —Cl, —Br, —CN, —NO2, or —OH; a C5-C30 heterocycloalkyl group unsubstituted or substituted with a C1-C20 alkyl group, a C1-C20 alkoxy group, —F, —Cl, —Br, —CN, —NO2, or —OH; and a group represented by —N(G1)(G2). At this time, G1 and G2 may each be independently hydrogen; a C1-C10 alkyl group; or a C6-C30 aryl group unsubstituted or substituted with a C1-C10 alkyl group.

The above-described “aryl group” refers to a polyunsaturated, aromatic, hydrocarbon substituent which may be a monocyclic or polycyclic ring fused or covalently bonded together. In addition, a Cn aryl group refers to an aryl group having n carbon atoms in a hydrocarbon ring which is a backbone of the aryl group, and the Cn aryl group may be substituted or unsubstituted.

The above-described “heteroaryl group” refers to an aryl group (or ring) containing one to four heteroatoms selected from nitrogen (N), oxygen (O), and sulfur (S) (in each separate ring in the case of polycyclic rings), and the nitrogen atom and the sulfur atoms may be oxidized in some cases, and the nitrogen atom(s) may be quaternized in some cases. The heteroaryl group may be bonded to the remaining portion of the molecule through a carbon atom or a heteroatom. In addition, a Cn heteroaryl group refers to a heteroaryl group having n carbon atoms in a hydrocarbon ring which is a backbone of the heteroaryl group, and the Cn heteroaryl group may be substituted or unsubstituted.

The above-described “alkyl group” is understood as particularly referring to a straight-chain, branched-chain, or cyclic hydrocarbon group generally having 1 to 20 carbon atoms. Examples of alkyl groups include methyl, ethyl, propyl, isopropyl, butyl, isobutyl, sec-butyl, tert-butyl, pentyl, neopentyl, hexyl, cyclopropyl, cyclobutyl, cyclopentyl, and cyclohexyl. A Cn alkyl group refers to an alkyl group having n carbon atoms in a hydrocarbon chain which is a backbone of the alkyl group, and the Cn alkyl group may be substituted or unsubstituted.

The above-described “hydroxyl group” refers to —OH.

The above-described “alkoxy group” refers to —O—(alkyl group) including —OCH3, —OCH2CH3, —O(CH2)2CH3, —O(CH2)3CH3, —O(CH2)4CH3, —O(CH2)5CH3, and similar compound thereto, and here, the alkyl group is the same as defined above.

The above-described “amine group” is a derivative of —NH3, and unless otherwise specified, it may mean a form in which a hydrogen atom is not replaced or replaced with a substituent such as an alkyl group, an aryl group, or a heteroaryl group in the position where the hydrogen atom is present, and an amine group in which one hydrogen is replaced with a substituent is referred to as a primary amine group, an amine group in which two hydrogens are replaced with substituents is referred to as a secondary amine group, and an amine group in which three hydrogens are replaced by substituents is referred to as a tertiary amine group. Examples include methylamine, dimethylamine, aniline, 3-nitroaniline, and the like. Here, the alkyl group, aryl group, and heteroaryl group are the same as defined above.

The above-described halide perovskite nanocrystal may have a structure of ABX3 (three-dimensional crystal structure), A4BX6 (zero-dimensional crystal structure), AB2X5 (two-dimensional crystal structure), A2BX4 (two-dimensional crystal structure), A2BX6 (zero-dimensional crystal structure), A2B+B3+X6 (three-dimensional crystal structure), A3B2X9 (two-dimensional crystal structure) or A′2Am-1BmX3m+1 (quasi-two-dimensional crystal structure) (m is an integer between 2 and 6). Preferably, it may have an ABX3 crystal structure.

At this time, A or A′ may be a monovalent organic cation, a monovalent inorganic cation, or a combination thereof. Examples of A or A′ include (CxH2x+1NH3)+, (C6H5CxH2x+1NH3)+, (CH(NH2)2)+, (CxH2x(NH3)2)+(NH4)+, (NF4)+, (NCl4)+, (N(CxH2x+1)4)+, ((CxH2x+1)2NH2)+, (C4H10N)+, (C3H5N2)+, (PH4)+, (PF4)+, (PCl4)+, (C(NH2)3)+, ((CxH2x+1)nNH3)2(CHNH3)n+, (CF3NH3 +, ((CxF2x+1)nNH3)2 (CFNH3)n+, ((CxF2x+1)nNH3)n+, (CH3PH3)+, (CH3AsH3)+, (CH3SbH3)+, (AsH4)+, (SbH4)+, a monovalent alkali metal ion (n is an integer from 1 to 100 and x is an integer from 1 to 100), or a combination thereof. Preferably, A or A′ may be a monovalent alkali metal ion, and more preferably, A or A′ may be Cs+.

In addition, B may be a metal ion, and preferably, B may be a divalent metal ion, a monovalent metal ion, a trivalent metal ion, or a combination thereof, and more preferably, B may be divalent Pb.

In addition, X may be F—, Cl—, Br—, I—, SCN—, OCN—, SeCN—, HCO2—, CH3COO—, or a combination thereof, and preferably, X may be a single halogen anion rather than a combination thereof, and more preferably, X may be Br—. Since the halide perovskite includes a pseudo-halide perovskite as described above, X may be an anion other than a halogen anion.

Next, the size of the above-described halide perovskite nanocrystal particles may range from 1 nm to 10 um. For example, the particle size may be 1 nm, 1.5 nm, 2 nm, 2.5 nm, 3 nm, 3.5 nm, 4 nm, 4.5 nm, 5 nm, 5.5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm. The particle size may be defined as a region where the lower value of any two numbers selected above is a minimum value and the larger value is a maximum value. Preferably, the particle size is 2 nm or more and 300 nm or less, and more preferably 3 nm or more and 30 nm or less. Meanwhile, the size of the crystal particles at this time means the size that does not consider the length of the ligand to be described below, that is, the size of the remaining portion excluding the ligand. When the size of the crystal particles is 1 μm or more, there may be a fundamental problem that excitons may not emit light but are separated into free charges and annihilated due to thermal ionization and delocalization of charge carriers within the large crystal. In addition, green and red nanocrystal particles may have a crystal particle size larger than or equal to the Bohr diameter as described above. The thermal ionization and delocalization of charge carriers gradually occur when the nanocrystal size exceeds 100 nm. When the nanocrystal size is 300 nm or more, the phenomena occur more, and when it is 1 μm or more, which corresponds to a bulk region, the phenomena are completely dominant.

The method of deriving the exciton Bohr diameter may be found in the research articles [ACS Nano, 2017, 11(7), pp 6586-6593; AIP Advances, 2018, 8, 025108], the Supporting Information, and the references listed in these articles [in particular, Nature Physics, 2015, 11, 582; Energy & Environmental Science, 2016, 9, 962; J. Phys. Chem. Lett., 2017, 8, 1851]. For example, the exciton Bohr diameter of MAPbBr3 may be about 10 nm. This may be smaller or larger than 10 nm depending on the material. The parameters to be used in such measurements should be obtained within the scope generally considered by those of ordinary skill in the art. According to recent research articles on dielectric constant (εr) as a function of frequency [Advanced Energy Materials, 2017, 7, 1700600; APL Materials, 2019, 7, 010901; Advanced Materials, 2019, 31, 1806671], the dielectric constant should not be determined using the value of the dynamic dielectric constant range higher than a high frequency (>1,000,000 Hz) but should be determined by considering the static dielectric constant (ε0=static dielectric constant) below 106 Hz. This is a range where an optical response occurs at a high frequency (approximately 1015 Hz), and ε∞ may be defined in this range. The dielectric constant used to calculate the exciton Bohr diameter must be a value between ε∞ and ε0. Considering that organic semiconductor materials typically have a dielectric constant of 3 to 5, the static dielectric constant of ionic halide metal halide perovskite materials must be much greater than this value. The dielectric constant of ionic halide metal halide perovskite materials has a value between 10 and 50 when measured at room temperature, more preferably between 20 and 35 at room temperature. The value may vary depending on the temperature, and it typically has a value between 20 and 100 or less depending on the temperature change. The CsPbBr3 material has a dielectric constant that is almost independent of temperature, but an organic-inorganic hybrid metal halide perovskite has a temperature dependency. In addition, the measurement must be carried out with a pure metal halide perovskite thin film without a ligand, and the value measured at normal room temperature must be entered into the formula. It is reasonable that in a typical metal halide perovskite semiconductor with a dielectric constant ranging from 1 eV to 3.5 eV, the dielectric constant of the metal halide perovskite should be at least twice that of an organic material. The dielectric constant may be measured using a typical LCR meter, or it may be obtained by measuring it with an impedance spectroscopy instrument and fitting it to an equivalent circuit. In addition, as shown in Nature Physics, 2015, 11, 582; Energy & Environmental Science, 2016, 9, 962; and J. Phys. Chem. Lett., 2017, 8, 1851, after obtaining the effective mass and exciton binding energy, it may be obtained using the formula

$${R}^{*} = {R}_{0} μ / {m}_{0} {ϵ}_{r}^{2}$$

(R*=exciton binding energy, R₀=atomic Rydberg constant, m₀=free electron mass, μ=reduced effective mass defined by

$$\frac{1}{μ} = \frac{1}{{m}_{h}} + \frac{1}{{m}_{e}} ,$$

mₕ=effective mass of hole, mₑ=effective mass of electron). The effective dielectric constant obtained in this manner and reported in AIP Advances, 2018, 8, 025108 is 11.4. At this time, the value of μ=0.117m0 was used. The exciton Bohr radius obtained at this time is 5.16 nm, and the exciton Bohr diameter is 10.32 nm (The research article describes that the exciton Bohr radius is 4.7 nm and the exciton Bohr diameter is 9.4 nm. However, this is considered to be a calculation error.)

The exciton Bohr diameter may be obtained by using the value of the effective mass of the metal halide perovskite and Mathematical Formula 1 below.

$$r = {a}_{0} {ε}_{r} \frac{{m}_{0}}{μ} \qquad [ Mathematical Formula 1 ]$$

Here, r may be the exciton Bohr radius, a0 may be the Bohr diameter of hydrogen (0.053 nm), εr may be the dielectric constant, μ=me×mh/(me+mh), me may be the effective electron mass, and mh may be the effective hole mass. Here, the Bohr diameter is twice the Bohr radius.

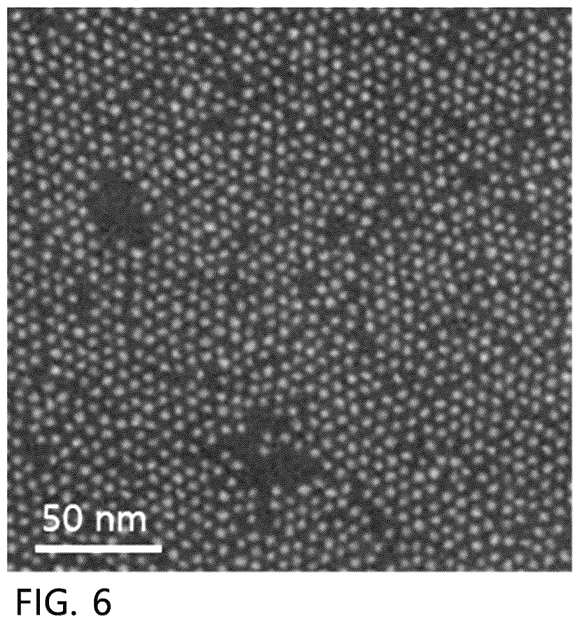

Next, as shown in FIG. 6, among the above-described halide perovskite nanocrystals, halide perovskite nanocrystal particles emitting blue light without including chloride anions (Cl—) should be quantum dots having a size smaller than the above-described Bohr diameter, and the size may be 3 nm to 5.5 nm. For example, the size may be 3.0 nm, 3.1 nm, 3.2 nm, 3.3 nm, 3.4 nm, 3.5 nm, 3.6 nm, 3.7 nm, 3.8 nm, 3.9 nm, 4.0 nm, 4.1 nm, 4.2 nm, 4.3 nm, 4.4 nm, 4.5 nm, 4.6 nm, 4.7 nm, 4.8nm, 4.9 nm, 5.0 nm, 5.1 nm, 5.2 nm, 5.3 nm, 5.4 nm, or 5.5 nm. Preferably, the size may be 3.5 to 4.5 nm to exhibit deep blue light. Here, the nanocrystal size refers to the average size of the nanocrystals measured by a transmission electron microscope (TEM). When the nanocrystal size is less than 3 nm, there may be a problem of emitting light in the ultraviolet region, and when it exceeds 5.5 nm, the nanocrystal may not emit blue light.

Next, the size of the halide perovskite nanocrystal particles emitting blue light and containing both bromine anions (Br—) and chloride anions (Cl—) may range from 3 nm to 30 nm. For example, the size may be 3 nm, 3.5 nm, 4 nm, 4.5 nm, 5 nm, 5.5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, or 30 nm. When the nanocrystal size is less than 3 nm, there may be a problem of emitting light in the ultraviolet region, and when it exceeds 30 nm, the effect of thermal ionization may increase, thereby decreasing the emission efficiency.

Next, the size of the halide perovskite nanocrystal particles emitting green or red light may range from 7 nm to 30 nm. The size may be 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, or 30 nm. When the nanocrystal size is less than 7 nm, the wavelength is blue-shifted due to the quantum confinement effect, and when it exceeds 30 nm, the thermal ionization effect may increase, thereby decreasing the emission efficiency.

A halide perovskite nanocrystal according to a preferred embodiment of the present invention may have an emission spectrum peak at a wavelength of 440 to 470 nm. More specifically, it may include a range in which the lower value of two numbers among 440 nm, 445 nm, 450 nm, 455 nm, 457 nm, 459 nm, 461 nm, 463 nm, 465 nm, 467 nm, and 470 nm is a lower limit and the higher value is an upper limit. More preferably, the halide perovskite nanocrystal may have an emission spectrum peak at 440 to 467 nm. When the halide perovskite nanocrystal has an emission spectrum peak at a wavelength of less than 440 nm, an additional measure to prevent ultraviolet rays is required because light in the ultraviolet region is emitted, and excellent emission efficiency and color purity may not be achieved because light in the visible light region is relatively reduced. When the emission spectrum peak appears at a wavelength of more than 470 nm, a deep blue emission spectrum may not be implemented due to a red shift, and excellent emission efficiency and color purity may not be achieved.

Meanwhile, among the above-described halide perovskite nanocrystals, halide perovskite nanocrystal particles emitting blue light without including chloride anions (Cl—) may have a size of 3 nm to 5.5 nm, and when the halide perovskite nanocrystal emits deep blue light at a wavelength of 440 nm to 470 nm, a red shift is prevented, so that excellent emission efficiency and color purity can be achieved.

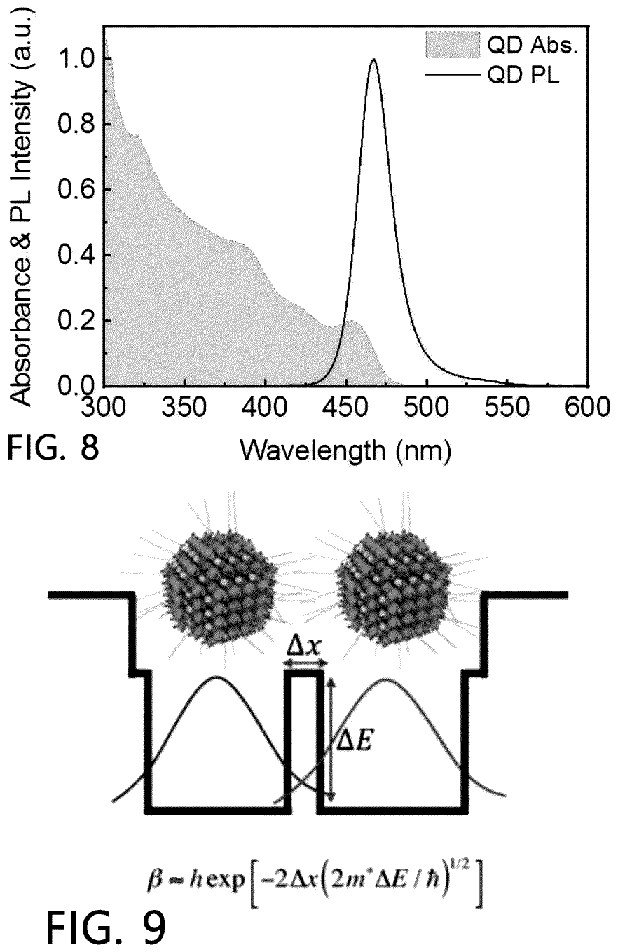

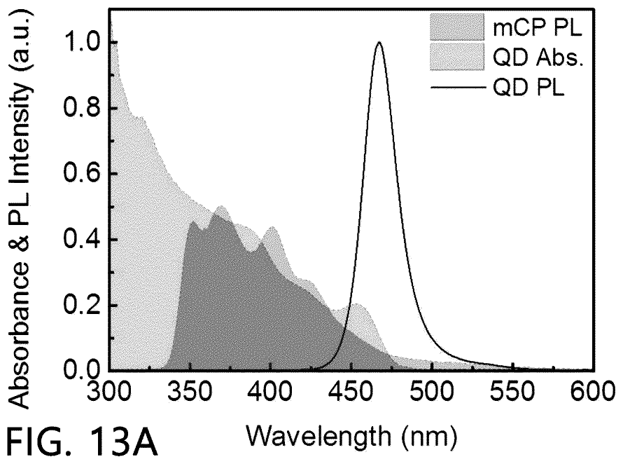

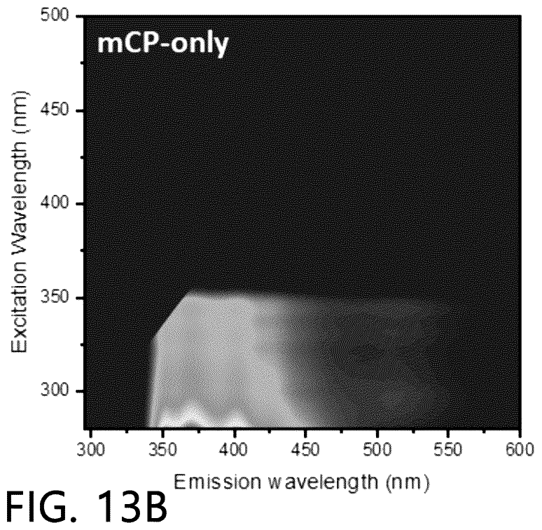

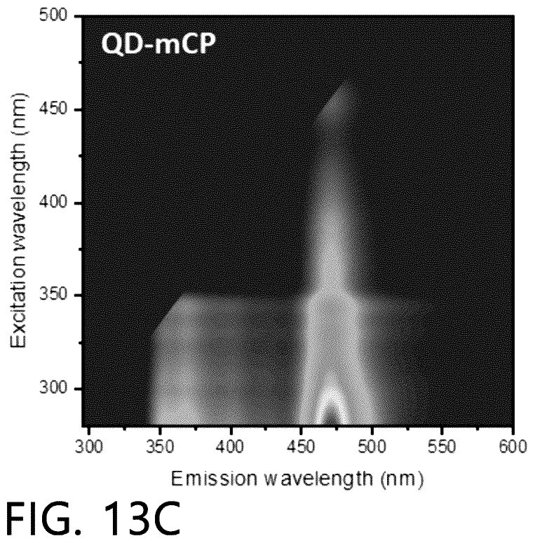

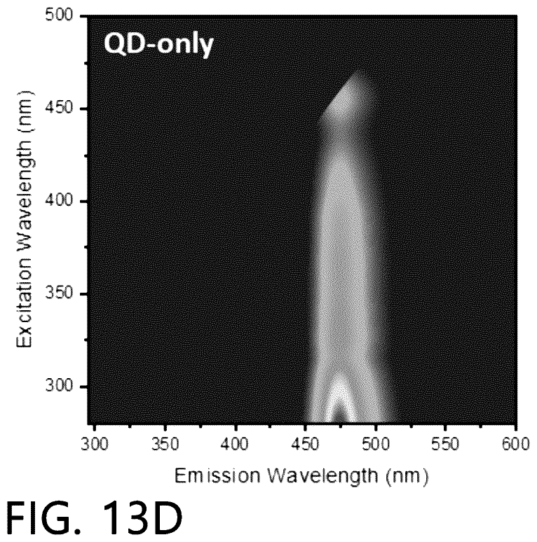

Most preferably, the halide perovskite nanocrystal may be a nanocrystal including a CsPbBr3 crystal. In particular, when only Br-is included in the X of the halide perovskite crystal without including Cl—, halide segregation and deep traps do not occur, which may lead to high quantum efficiency. In addition, referring to FIG. 8, a nanocrystal including a CsPbBr3 crystal may emit light in a deep blue region and exhibit excellent absorption characteristics near an ultraviolet region when it satisfies the above-described nanocrystal size. Accordingly, referring to FIGS. 13A to 13C, even when an organic host (e.g., 1,3-di-9-carbazolylbenzene (mCP)) that emits light near an ultraviolet region is included in emitters, which will be described later, the energy of that region is transferred to the nanocrystal and re-emitted, so that high efficiency and color purity in a deep blue region can be ensured.

The above-described halide perovskite nanocrystal may be surrounded on the surface by an organic amine, an organic acid, an organic ammonium ligand, or an inorganic ligand.

The amine ligand may be selected from N,N-diisopropylethylethylamine, ethylenediamine, hexamethylenediamine, methylamine, N,N,N,N-tetramethylethylenediamine, triethylamine, diethanolamine, and 2,2-(ethylenedioxyl) bis-(ethylamine), but is not limited thereto.

The organic acid may include a carboxylic acid and phosphonic acid, and the carboxylic acid may be selected from 4,4′-azobis(4-cyanovaleric acid), acetic acid, 5-aminosalicylic acid, acrylic acid, 1-aspartic acid, 6-bromohexanoic acid, bromoacetic acid, dichloroacetic acid, ethylenediaminetetraacetic acid, isobutyric acid, itaconic acid, maleic acid, maleimidobutyric acid, 1-malic acid, 4-nitrobenzoic acid, 1-pyrenecarboxylic acid, hexanoic acid, octanoic acid, decanoic acid, undecanoic acid, dodecanoic acid, hexadecenoic acid, octadecanoic acid, and oleic acid.

The phosphonic acid may be selected from n-hexylphosphonic acid, n-octylphosphonic acid, n-decylphosphonic acid, n-dodecylphosphonic acid, n-tetradecylphosphonic acid, n-hexadecylphosphonic acid, and n-octadecylphosphonic acid.

The organic ligand may be in a fluorinated form. For example, the organic ligand may be 2-fluorophenylboronic acid, 3,5-diformyl-2-fluorophenylboronic acid, 3-chloro-4-fluorophenylboronic acid, 4-cyano-3-fluorobenzoic acid, 1-Fmoc-3-fluorophenylalanine, 1-Fmoc-4-fluorophenylalanine, methyl 6-fluorochromone-2-carboxylic acid, 4-fluorobenzoic acid, 2-fluorobenzoic acid, 2-fluorobenzylamine, 2-fluorocinnamic acid, 2-fluorophenyl isothiocyanate, 4-fluorobenzenesulfonic acid, 4-fluorobenzylamine, 4-fluorophenyl 4-isothiocyanate, fluorophenylacetic acid, fluorocinnamic acid, (3-fluoro-4-methylphenyl)acetic acid, (3-fluoro-5-isopropoxyphenyl)boronic acid, (3-fluoro-5-methoxycarbonylphenyl)boronic acid, (3-fluoro-5-methylphenyl)boronic acid, (4-fluoro-2-methoxyphenyl)oxoacetic acid, (4-fluoro-3-methoxyphenyl)acetic acid, (4-fluoro-3-methoxyphenyl)boronic acid, or a combination thereof, but is not limited thereto.

In addition, preferably, the fluorinated organic compound may be in the form of a perfluorinated compound. The perfluorinated compound may be a perfluorinated alkyl halide, a perfluorinated aryl halide, a fluorochloroalkene, a perfluoroalcohol, a perfluoamine, a perfluorocarboxylic acid, a perfluorosulfonic acid, or a derivative thereof, but is not limited thereto.

The perfluorinated alkyl halide and the perfluorinated aryl halide may be trifluoroiodomethane, pentafluoroethyl iodide, perfluorooctyl bromide (perflubron), dichlorodifluoromethane, or a derivative thereof, but are not limited thereto.

The fluorochloroalkene may be chlorotrifluoroethylene, dichlorodifluoroethylene, or a derivative thereof, but is not limited thereto.

The fluorochloroalkene may be chlorotrifluoroethylene, dichlorodifluoroethylene, or a derivative thereof, but is not limited thereto.

The perfluorocarboxylic acid may be trifluoroacetic acid, heptafluorobutryric acid, pentafluorobenzoic acid, perfluorooctanoic acid, perfluorononanoic acid, or a derivative thereof, but is not limited thereto.

The perfluorosulfonic acid may be triflic acid, perfluorobutanesulfonic acid, perfluorobutane sulfonamide, perfluorooctanesulfonic acid, or a derivative thereof, but is not limited thereto.

The ligand may be trioctylphosphine oxide (TOPO), trioctylphosphine (TOP), triethylphosphine oxide, tributylphosphine oxide, or a derivative thereof, but is not limited thereto.

The organic ammonium ligand may be a ligand having a structure of alkyl-X. The alkyl may be selected from the group consisting of acylic alkyl (CnH2n+1); polyhydric alcohols (CnH2n+1OH) including primary alcohols, secondary alcohols, and tertiary alcohols; alkylamines (alkyl-N) including hexadecyl amine, 9-octadecenylamine, and 1-amino-9-octadecene (C19H37N); p-substituted aniline, phenyl ammonium, and fluorinated ammonium, and X may be Cl, Br, or I.

The inorganic ligand may include structures of AX, BX2, and CX3.

At this time, A is a monovalent inorganic cation. Examples of A include Li+, Na+, K+, Rb+, Cs+, and Fr+, but are not limited thereto.

B is a divalent inorganic cation. Examples of B include Mg2+, Ca2+, Sr2+, Ba2+, Zn2+, Cd2+, Hg2+, Mn2+, Fe2+, Co2+, Ni2+, Cu2+, Pb2+, Sn2+, Ti2+, V2+, Cr2+, U2+, Th2+, and Be2+, but are not limited thereto.

C is a trivalent inorganic cation, and examples of C include Al3+, Fe3+, Cr3+, Au3+, Ga3+, In3+, Sc3+, Y3+, La3+, Ce3+, Pr3+, Nd3+, Sm3+, Eu3+, Gd3+, Tb3+, Dy3+, Ho3+, Er3+, Tm3+, and Yb3+, but are not limited thereto.

In addition, X may be F—, Cl—, Br—, I—, SCN—, OCN—, SeCN—, HCO2—, or CH3COO—, but is not limited thereto.

Meanwhile, the halide perovskite nanocrystal particles may be bulk polycrystalline grains, and the above-described acyl halide and ligand surround the grains.

Next, the halide perovskite nanocrystal particles, which are the above-described bulk polycrystalline grains, may have a crystal grain size of 1 nm to 10 um or less. For example, the size may be 1 nm, 1.5 nm, 2 nm, 2.5 nm, 3 nm, 3.5 nm, 4 nm, 4.5 nm, 5 nm, 5.5 nm, 6 nm, 7 nm, 7.5 nm, 8 nm, 8.5 nm, 9 nm, 9.5 nm, 10 nm, 10.5 nm, 11 nm, 11.5 nm, 12 nm, 12.5 nm, 13 nm, 13.5 nm, 14 nm, 14.5 nm, 15 nm, 16 nm, 17 nm, 18 nm, 19 nm, 20 nm, 25 nm, 30 nm, 35 nm, 40 nm, 45 nm, 50 nm, 55 nm, 60 nm, 65 nm, 70 nm, 75 nm, 80 nm, 85 nm, It can be 90 nm, 95 nm, 100 nm, 150 nm, 200 nm, 250 nm, 300 nm, 350 nm, 400 nm, 450 nm, 500 nm, 600 nm, 700 nm, 800 nm, 900 nm, 1 μm, 2 μm, 5 μm, or 10 μm.

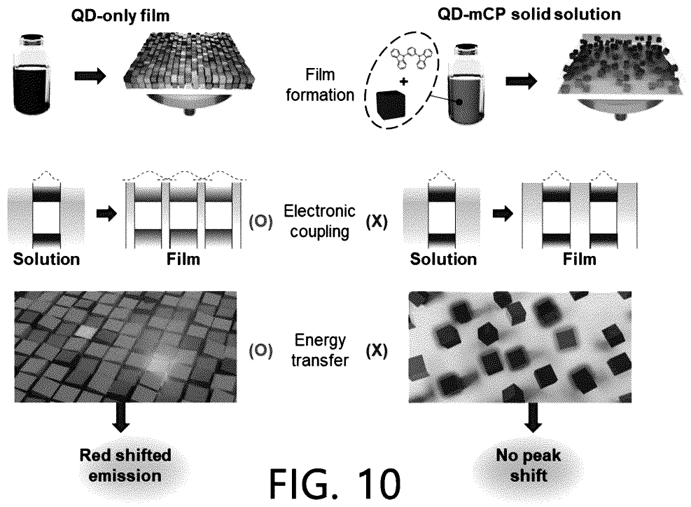

In order to solve the above-described problem, halide perovskite nanocrystal particle emitters including the above-described halide perovskite nanocrystal particles and an organic host are provided. The organic host used in the present invention has a function of suppressing energy transfer and electronic coupling between halide perovskite nanocrystals within the emitters. In other words, referring to FIGS. 10, 13C, 13D, 14A, 14B, and 16A to 16E, the above-described organic host may uniformly and widely disperse nanocrystals within the emitters. Through this, the organic host can suppress energy transfer and electronic coupling between nanocrystals within the emitters, thereby preventing a red shift, so that the emitters including the organic host and the nanocrystal can emit deep blue light and achieve high emission efficiency. Accordingly, it is expected that the organic host can be actively utilized in next-generation displays.

The average distance between the halide perovskite nanocrystal particles may be 4 to 12 nm. Preferably, it may be 7 to 10 nm. More specifically, it may include a range in which the lower value of two numbers among 4 nm, 4.5 nm, 5 nm, 5.5 nm, 6 nm, 6.5 nm, 7 nm, 7.5 nm, 8 nm, 8.5 nm, 9 nm, 9.5 nm, 10 nm, 10.5 nm, 11 nm, 11.5 nm, and 12 nm is a lower limit and the higher value is an upper limit. The average distance between nanocrystals was measured by mathematically dividing the number of halide perovskite nanocrystal particles within the emitter volume.

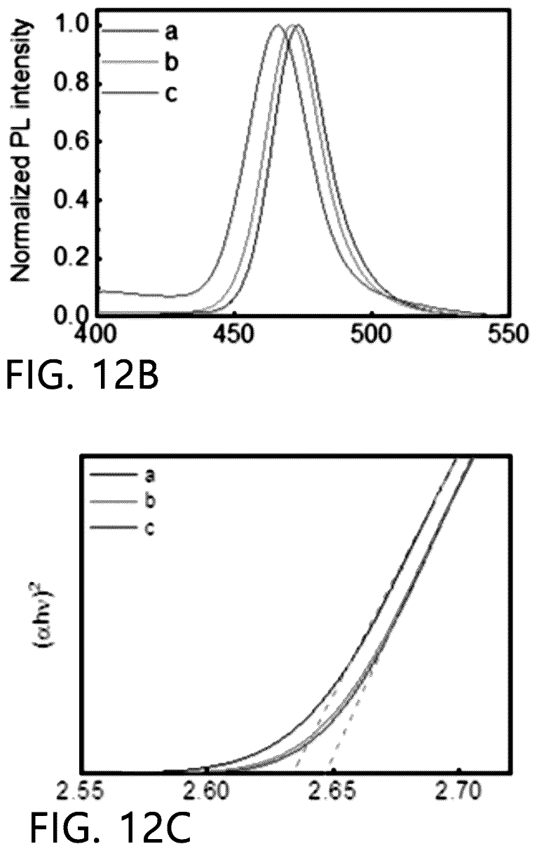

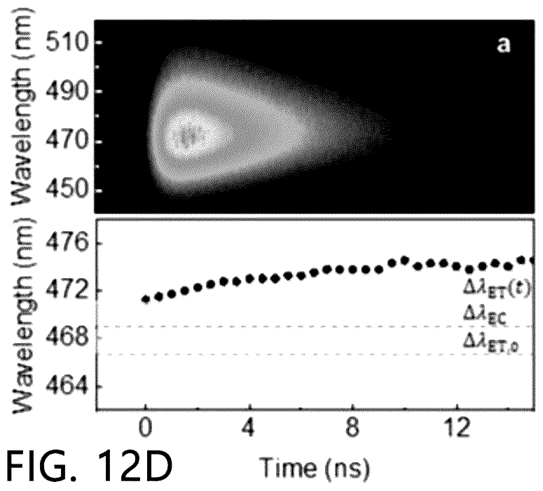

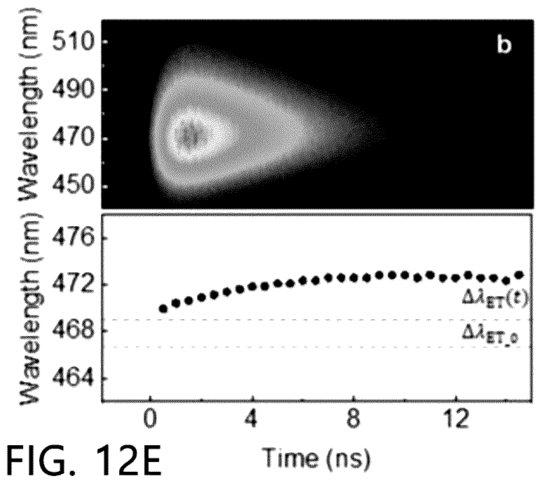

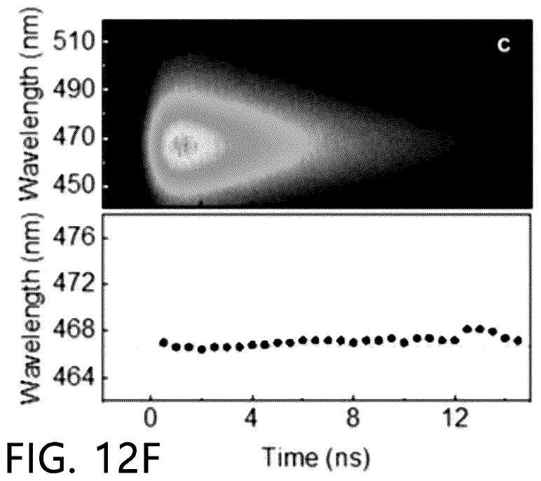

Referring to FIGS. 12A and 12B, it can be seen that as the average distance between halide perovskite nanocrystal particles increases, the wavelength value of the emission spectrum peak of the emitters decreases. This is a result of suppressing a red shift of the emitters. In addition, referring to FIG. 12C, as the average distance between halide perovskite nanocrystal particles increases, the band gap of the emitters increases, and accordingly, electronic coupling is suppressed. This is because, as shown in FIG. 9, as the distance between halide perovskite nanocrystal particles increases, the energy barrier for electronic coupling increases, and thus electronic coupling is suppressed. Specifically, referring to FIG. 9, electronic coupling occurs when wave functions overlap between adjacent halide perovskite nanocrystal particles. As the size of the nanocrystal decreases, stronger coupling may occur due to a high surface ratio, and it is known that such electronic coupling is exponentially inversely proportional to the interdot distance between nanocrystals and its energy barrier. The present invention can effectively suppress electronic coupling by mixing halide perovskite nanocrystals with an organic host so that the interdot distance between the particles increases. In addition, referring to FIGS. 12D to 12F, energy transfer in the emitters is suppressed as the average nanocrystal distance increases. In other words, when the average nanocrystal distance is less than 4 nm, there may be a problem in that a red shift may occur and the emitters may not emit blue light because energy transfer and electronic coupling within the emitters are not suppressed. When the average distance of nanocrystals exceeds 12 nm, the red shift prevention effect is minimal but the density of nanocrystals decreases, which may cause a problem in that the emission efficiency of the emitters decreases.

In addition, referring to FIG. 8, when the nanocrystal included in the above-described perovskite nanocrystal particle emitters includes a CsPbBr3 crystal, when the average distance between nanocrystals is 4 to 12 nm, the Forster energy transfer is suppressed, so that emission efficiency can be further improved. In the case of the nanocrystal including the CsPbBr3 crystal, the absorption region and the emission region of the emitters themselves overlap due to the small Stokes shift. This causes the Forster energy transfer to occur between nanocrystals. It is known that the Forster energy transfer efficiency is inversely proportional to the sixth power of the distance between a donor and an acceptor. Thus, as the distance between nanocrystals increases, the Forster energy transfer may decrease. Accordingly, in the case of conventional emitters composed only of halide perovskite nanocrystals, since the nanocrystals are in direct contact with adjacent nanocrystals, the Foster energy transfer occurs very easily. Accordingly, the present invention may suppress Foster energy transfer by mixing an organic host with halide perovskite nanocrystals so that the halide perovskite nanocrystals are dispersed in the organic host at a low concentration, thereby increasing the distance between the halide perovskite nanocrystals.

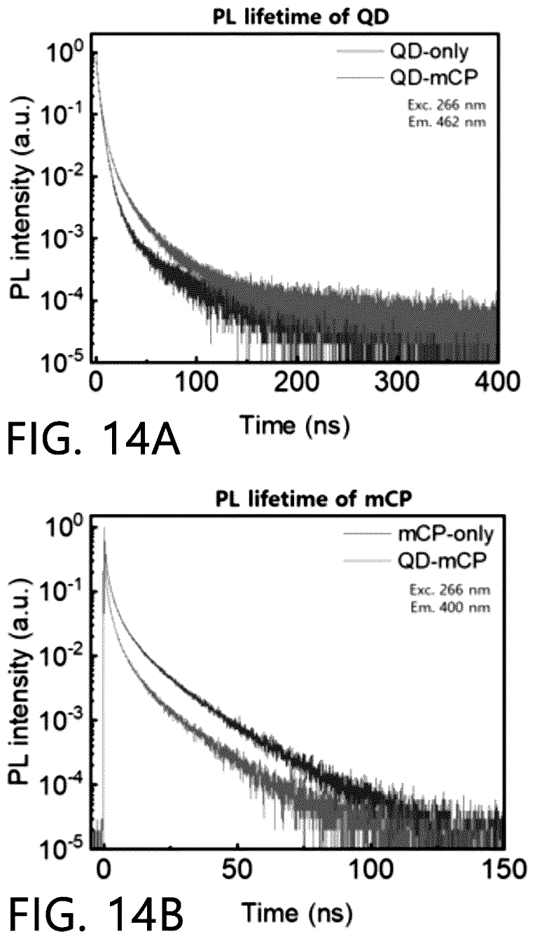

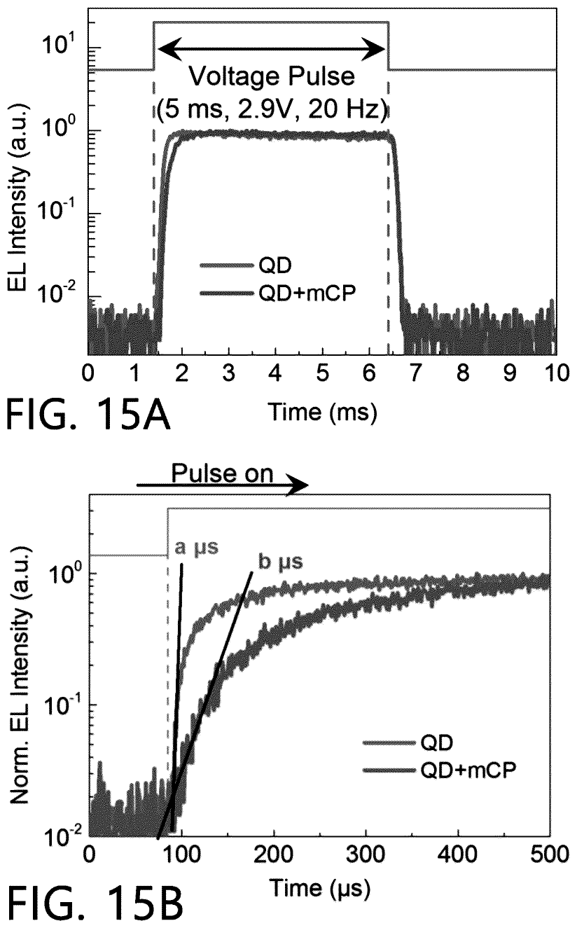

In addition, the above-described organic host may have semiconductor properties. Preferably, the organic host may be an n-type semiconductor, a p-type semiconductor, and an ambipolar semiconductor. Through this, when used on a light-emitting device, the organic host may receive charges and transfer energy to halide perovskite nanocrystals, which can be confirmed in FIGS. 13A to 13C and FIG. 14B. The organic host can ultimately improve the external quantum efficiency of a light-emitting device including emitters containing the organic host.

Specifically, referring to FIG. 14B, it can be confirmed that the photoluminescence lifetime of the emitters including an organic host (mCP) and a halide perovskite nanocrystal is shorter than that of the emitters including only the organic host (mCP) in the same wavelength range. This can be seen as a result of the mCP serving as an organic host and effectively transferring energy to the halide perovskite nanocrystal. As described above, by forming emitters by mixing an organic host with halide perovskite nanocrystals, the present invention can improve the problem of emission efficiency reduction due to energy transfer and electronic coupling between existing halide perovskite nanocrystals.

Furthermore, by modifying the nanocrystal surface and incorporating an organic host into the emitters, the nanocrystals can be dispersed more effectively, and a red shift can be prevented most effectively, so that the emitters can exhibit excellent emission efficiency.

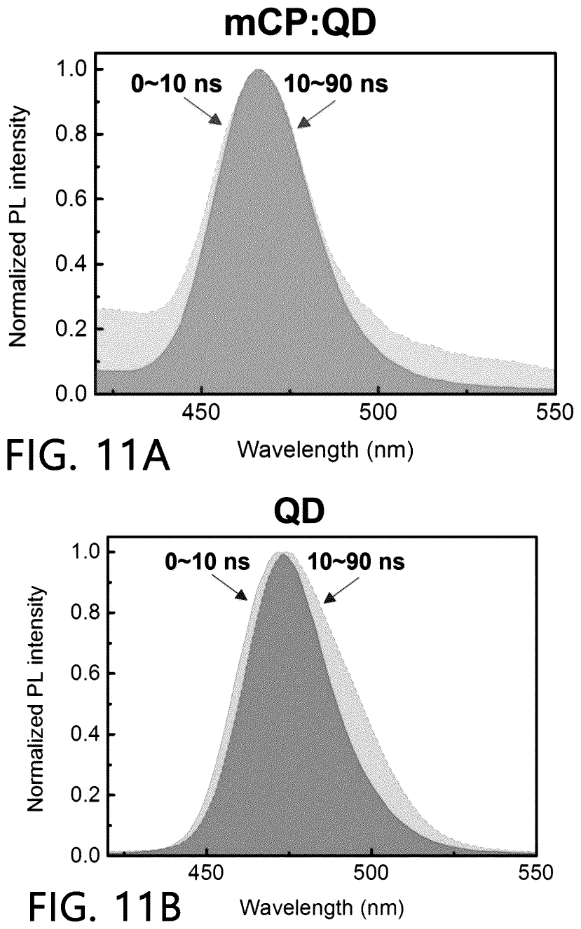

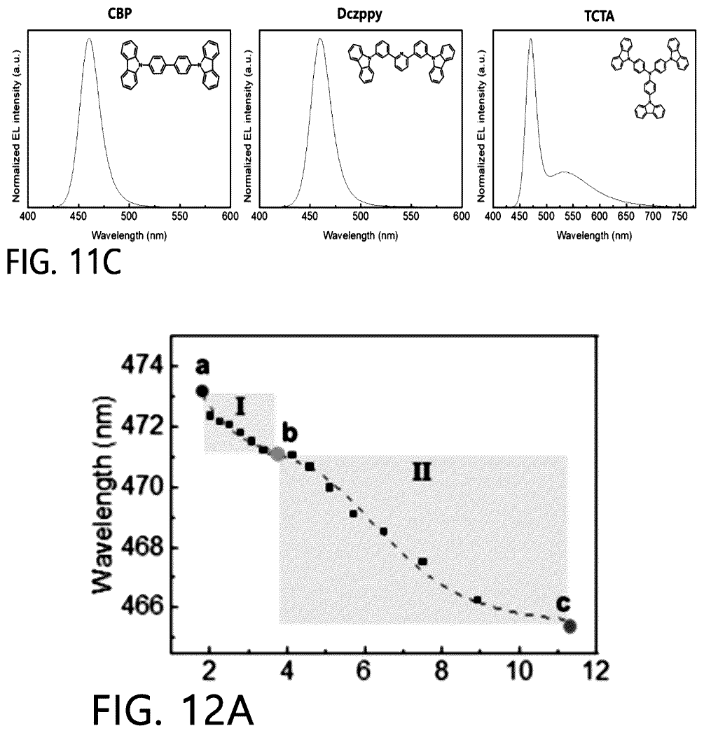

An organic host according to a preferred embodiment of the present invention may have a highest occupied molecular orbital (HOMO) energy level of −6.0 eV or less. When the HOMO energy level exceeds −6.0 eV, emitters including the organic host may form an exciplex in relation to an electron transport layer. Referring to FIG. 11C, the organic hosts 1,3-di-9-carbazolylbenzene (mCP), 4′-bis (N-carbazolyl)-1,1′-biphenyl (CBP) and 2,6-bis[3′(N-carbazolyl)phenyl]pyridine (DCzPPy) having a HOMO energy level of −6.0 eV or lower according to an embodiment of the present invention did not exhibit exciplex emission, but the organic host 4,4′,4″-tris(carbazol-9-yl)triphenylamine (TCTA) having a HOMO energy level exceeding −6.0 eV exhibited exciplex emission.

The above-described organic host may be a carbazole derivative. Examples of the carbazole derivative include 1,3-di-9-carbazolylbenzene (mCP), 3-[4-(9-phenanthryl)-phenyl]-9-phenyl-9H-carbazole (PCPPn), 3-[4-(1-naphthyl)-phenyl]-9-phenyl-9H-carbazole (PCPN), 4,4′-bis(N- carbazolyl)-1,1′-biphenyl (CBP), 3,6-bis(3,5-diphenylphenyl)-9-phenylcarbazole (CzTP), 1,3,5-tris[4-(N-carbazolyl)phenyl]benzene (TCPB), and 9-[4-(10-phenyl-9-anthracenyl)phenyl]-9H-carbazole (CzPA).

Preferably, the organic host may be a carbazole derivative having a HOMO energy level of −6.0 eV or lower. This has a better exciplex formation prevention effect. Examples of carbazole derivatives having a HOMO energy level of −6.0 eV or lower include SimCP, mCBP, mCP, CBP, and DCzPPy. More preferably, it may be mCP, CBP, and DCzPPy, and the organic hosts are represented by Chemical Formulas 2 to 4, respectively. Most preferably, it may be mCP.

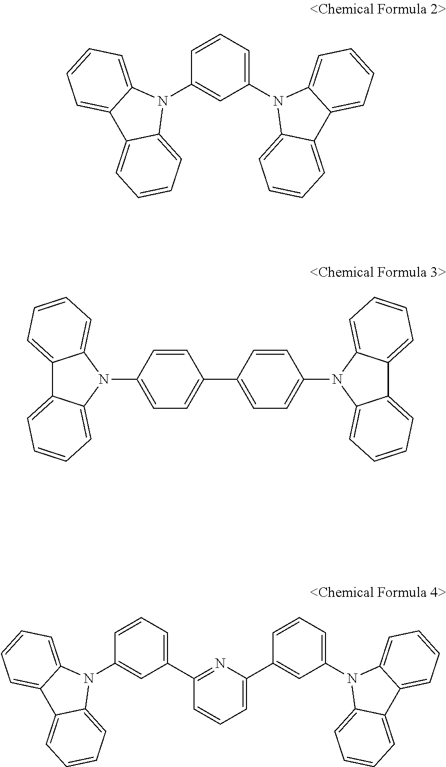 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

1 to 60 parts by weight of the above-described nanocrystal may be mixed based on 100 parts by weight of the above-described organic host. Preferably, 5 to 30 parts by weight may be mixed. More preferably, 10 to 20 parts by weight may be mixed. More specifically, it may include a range in which the lower value of two numbers among 1, 2, 3, 4, 5, 6, 7, 8, 9, 10, 10.5, 11, 11.5, 12, 12.5, 13, 13.5, 14, 14.5, 15, 15.5, 16, 16.5, 17, 17.5, 18, 18.5, 19, 19.5, 20, 25, 30, 35, 40, 45, 50, 55, and 60 parts by weight is a lower limit and the higher value is an upper limit. When the amount of nanocrystals is less than 1 part by weight, a problem of low efficiency may occur due to insufficient energy transfer from the organic host, and when the amount of nanocrystals exceeds 60 parts by weight, a problem may occur in which the nanocrystals may not be separated from each other by a sufficient distance within the emitters, and thus a red shift may not be effectively prevented.

Perovskite nanocrystal particle emitters according to a preferred embodiment of the present invention may have an emission spectrum peak at a wavelength of 420 to 467 nm. Preferably, the emitters may have an emission spectrum peak at 440 to 467 nm, and more specifically, in a range in which the lower value of two numbers among 420 nm, 425 nm, 430 nm, 435 nm, 440 nm, 445 nm, 450 nm, 455 nm, 457 nm, 459 nm, 461 nm, 463 nm, 465 nm, and 467 nm is a lower limit and the higher value is an upper limit. When the emitters have an emission spectrum peak at a wavelength of less than 420 nm, an additional measure to prevent ultraviolet rays is required because light in the ultraviolet region is emitted, and excellent emission efficiency and color purity may not be achieved because light in the visible light region is relatively reduced. When the emission spectrum peak appears at a wavelength of more than 467 nm, a deep blue emission spectrum may not be implemented due to a red shift, and excellent emission efficiency and color purity may not be achieved.

Meanwhile, the thickness of the above-described perovskite nanocrystal particle emitters may be 10 to 100 nm.

Next, a method of manufacturing halide perovskite nanocrystal particle emitters is described. The manufacturing method of the above-described perovskite nanocrystal particle emitters includes: preparing a coating solution including the above-described halide perovskite nanocrystal and an organic host; and applying the coating solution to manufacture perovskite nanocrystal particle emitters.

The solvent used in the preparation of the coating solution including the perovskite nanocrystal particles and the organic host must be capable of dissolving the perovskite nanocrystal particles and the organic host. The above-described solvent may include toluene, xylene, chlorobenzene, chloroform, tetrahydrofuran, cyclohexanone, and a combination thereof, and more preferably, it may be toluene or chlorobenzene.

The amounts of the organic host and the halide perovskite nanocrystal included in the coating solution may be 0.01 to 50 parts by weight and 0.01 to 20 parts by weight, respectively, based on 100 parts by weight of the solvent of the above-described coating solution for emitters.

Meanwhile, in the above-described manufacturing method, the organic host may have a highest occupied molecular orbital (HOMO) energy level of −6.0 eV or less.

In addition, in the above-described manufacturing method, the organic host may be a carbazole derivative.

In addition, in the above-described manufacturing method, the organic host may be selected from the group consisting of Chemical Formulas 2 to 4 below.

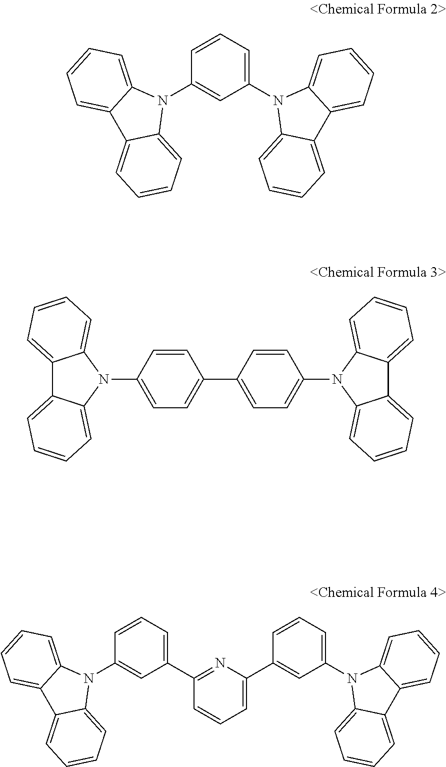 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

In addition, in the emitters of the halide perovskite nanocrystal particles manufactured by the above-described manufacturing method, 1 to 60 parts by weight of the nanocrystals may be mixed based on 100 parts by weight of the organic host.

Since the details of the organic host are the same as described above, specific details are omitted.

In order to solve the above-described problem, there is provided a method of preparing a coating solution for emitters, the method including: a step of mixing a first solution containing halide perovskite nanocrystals and a second solution containing an organic host for suppressing energy transfer and electronic coupling between the halide perovskite nanocrystals.

In the above-described method of preparing a coating solution for emitters, as a preliminary step of the step of mixing the first solution and the second solution, the coating solution preparation method may further include: a first preliminary step of preparing a third solution containing a first halide perovskite precursor and a fourth solution containing a second halide perovskite precursor; and a second preliminary step of preparing halide perovskite nanocrystals by mixing the third solution and the fourth solution.

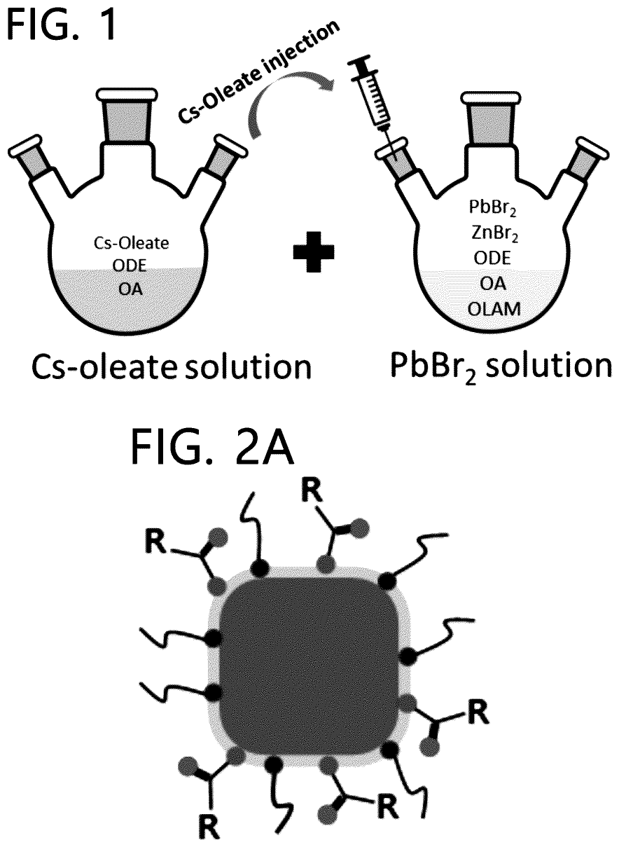

Hereinafter, the above-described method of preparing a coating solution for emitters will be described with reference to FIG. 1.

First, as the above-described first preliminary step, a third solution containing a first halide perovskite precursor and a fourth solution containing a second halide perovskite precursor are prepared.

The above-described first halide perovskite precursor may be a precursor containing the above-described A, and preferably it may be a precursor containing a Cs ion. More preferably, it may be a CsOAc, Cs2CO3, or Cs20 precursor, and most preferably, it may be a Cs2CO3 precursor.

The above-described second halide perovskite precursor may be a precursor including the above-described B and/or a precursor including Zn, and preferably, the precursor including B may be a precursor including Pb ions. More preferably, the precursor including B may be PbBr2, PbO, Pb(OAc)2, or Zn(St)2, and the precursor including Zn may be ZnBr2, ZnO, Zn(OAc)2, or Zn(St)2. Most preferably, the second halide perovskite precursor may be a PbBr2 precursor or a ZnBr2 precursor.

Since any solvent may be used as a solvent of the above-described third solution without limitation as long as it is capable of dissolving the first halide perovskite precursor, the present invention does not specifically limit the solvent. Preferably, the solvent may be an organic solvent, more preferably, 1-octadecene, 1-octene, or 1-tetradecene. Most preferably, it may be 1-octadecene.

Since any solvent may be used as a solvent of the above-described fourth solution without limitation as long as it is capable of dissolving the second halide perovskite precursor, the present invention does not specifically limit the solvent. Preferably, the solvent may be an organic solvent, most preferably 1-octadecene.

The above-described third solution and/or fourth solution may be mixed with an organic or inorganic ligand. Since the organic or inorganic ligand is the same as described above, specific details are omitted. As the organic or inorganic ligand is mixed together, the formed halide perovskite nanocrystals may be uniformly dispersed and stabilized in the coating solution or emitters. Preferably, it may be an organic ligand having a long chain, and most preferably, it may be oleylamine or oleic acid.

Meanwhile, as the above-described organic or inorganic ligand is mixed together, the halide perovskite nanocrystal particles may be surrounded by an organic or inorganic ligand in the method of manufacturing halide perovskite nanocrystal particle emitters of the present invention.

Next, as the above-described second preliminary step, the third solution and the fourth solution prepared in the first preliminary step are mixed to manufacture halide perovskite nanocrystals.

Referring to FIG. 1, the above-described mixing may be mixing through a hot-injection method. In the mixing through a hot-injection method, uniformly sized halide perovskite nanocrystals with a dense size distribution can be formed, and a light-emitting device including the nanocrystals can achieve excellent emission efficiency and color purity.

The temperature during the above-described mixing through the hot-injection method may be set without limitation as long as it is a temperature at which halide perovskite nanocrystals may be manufactured. The mixing can be performed preferably at 60 to 100° C., and preferably at 70 to 90° C.

More specifically, the mixing may be performed by maintaining the fourth solution at a target temperature and then injecting a part of the third solution.

The mixing ratio of the above-descried third solution and fourth solution may be 1:100 to 1:5 by volume. When the mixing ratio of the fourth solution exceeds 1:100 by volume, a problem of little or no nanocrystal formation may occur due to an insufficient amount of the Cs precursor, and when the mixing ratio of the fourth solution is less than 1:5 by volume, a problem of synthesizing Cs4PbBr6 or nanoplatelets may occur.

The above-described method of preparing a coating solution for emitters may further include a step of performing surface treatment or ligand substitution on the halide perovskite nanocrystals manufactured in the second preliminary step with an acyl halide. In other words, the above-described halide perovskite nanocrystal particle emitters may be obtained by preparing a halide perovskite nanocrystal particle solution or thin film, and surface-treating or ligand-substituting the halide perovskite nanocrystal using an additive solution containing an acyl halide of Chemical Formula 1 below in the halide perovskite nanocrystal particle solution or thin film.

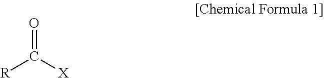

In Chemical Formula 1, X is a halogen element corresponding to F, Cl, Br, or I, and R is a substituted or unsubstituted aromatic ring or a substituted or unsubstituted hydrocarbon group.

Specific details regarding R are the same as described above and thus are omitted.

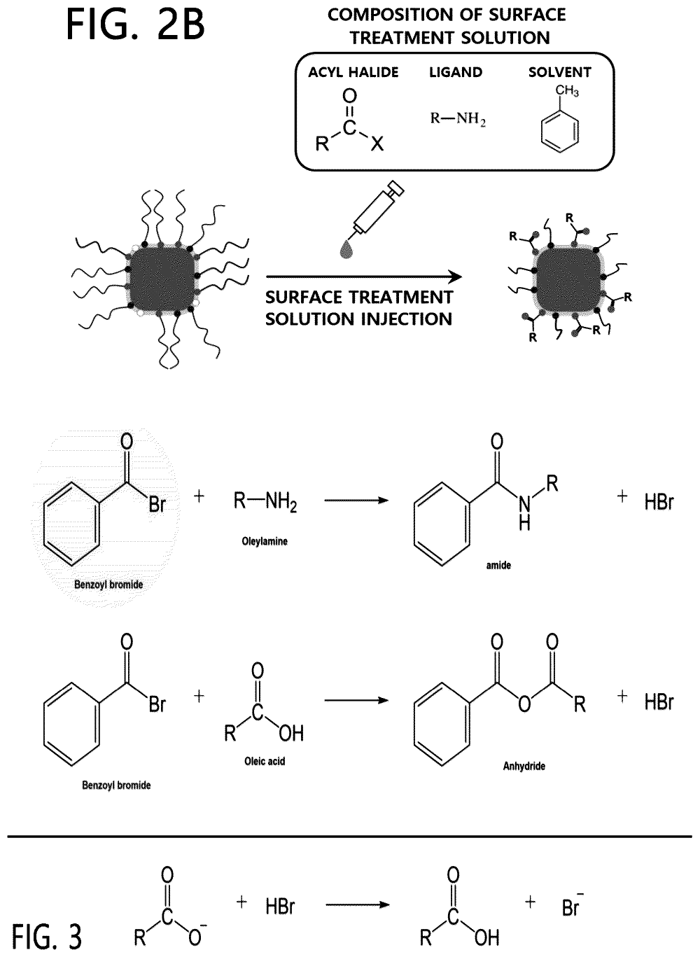

Specifically, as shown in FIGS. 2A, 2B, and 3, after the halide perovskite nanocrystals manufactured in the second step are purified, an additive solution containing an acyl halide may be injected into the nanocrystals to perform surface-treatment or ligand-substitution of the nanocrystal with the acyl halide. At this time, as shown in FIG. 3, the acyl halide partially reacts with a ligand added together to the additive solution to generate hydrogen bromide, and through the hydrogen bromide, surface defects such as bromine vacancy defects of the halide perovskite nanocrystal can be removed, and the organic host and nanocrystals can be uniformly dispersed in the coating solution, thereby improving the emission efficiency of the emitters coated with the coating solution.

The above-described purification may be performed by mixing a solvent with the halide perovskite nanocrystals, coagulating the nanocrystals, and then centrifuging them to precipitate. More specifically, the above-described purification may be performed by mixing a hydrophilic solvent with the halide perovskite nanocrystals, coagulating the nanocrystals, and then centrifuging them to precipitate, removing the supernatant from the precipitated state, redispersing the precipitated halide perovskite nanocrystals in a hydrophobic solvent, coagulating them again by mixing the above-described hydrophilic solvent, and then extracting them using a centrifuge.

According to an embodiment, the above-described halide perovskite nanocrystals may be those that have undergone the above-described purification process and then further undergone the same purification process.

The above-described hydrophilic solvent may be one or more selected from methyl acetate, ethyl acetate, methanol, ethanol, acetone, and isopropyl alcohol. Preferably, the hydrophilic solvent may be methyl acetate.

The above-described hydrophobic solvent may be one or more selected from hexane, chloroform, chlorobenzene, toluene, xylene, and cyclohexane. Preferably, the hydrophobic solvent may be hexane.

The above-described additive solution may further include a ligand as well as an acyl halide. More specifically, the above-described additive solution may be a solution containing an acyl halide of Chemical Formula 1 below that provides a bromine anion and a molecule capable of being bound to the surface of halide perovskite nanocrystal particles; and a ligand.

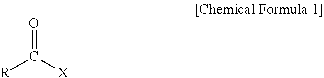

In Chemical Formula 1, X is a halogen element corresponding to F, Cl, Br, or I, and R is a substituted or unsubstituted aromatic ring or a substituted or unsubstituted hydrocarbon group. The acyl halide of Chemical Formula 1 contained in the above-described additive solution may be acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, 2-chloropropionyl chloride, acetyl iodide, propionyl iodide, valeryl iodide, benzoyl iodide, bromoacetyl iodide, 2-bromopropionyl iodide, or 2-bromobutyryl iodide, but is not limited thereto. The ligand contained in the above-described additive solution may be aniline, benzylamine, phenethylamine, 3-phenyl-1-propylamine, 4-phenylbutylamine, ethylamine, propylamine, butylamine, pentylamine, isobutylamine, or isopropylamine, but is not limited thereto.

In addition, the solvent of the above-described additive solution may be a nonpolar solvent including one of toluene, xylene, chlorobenzene, chloroform, tetrahydrofuran, cyclohexanone, or a combination thereof, which is a solvent capable of dissolving a precursor providing a bromine anion and a precursor providing a molecule capable of being bound to the surface of the nanocrystal, and most preferably, it may be toluene.

The above-described additive solution contains 0.01 to 50 parts by weight of an acyl halide and a ligand based on 100 parts by weight of the nonpolar solvent. When the amount of the acyl halide and the ligand is less than 0.01 parts by weight, the surface treatment of the halide perovskite nanocrystal may not be sufficient, resulting in low emission intensity, and when the amount of the acyl halide and the ligand is more than 50 parts by weight, there is a problem in that the emission intensity of the halide perovskite nanocrystal may decrease due to excessive ligand substitution, and thus the size thereof may further increase and the dispersibility may decrease.

Meanwhile, among the related art documents, according to the research articles J. Am. Chem. Soc. 2018, 140, 7, 2656-2664 and Journal of Photochemistry & Photobiology, A: Chemistry 442 (2023) 114760, there are reports on the use of benzoyl halide, one of the acyl halides, as a precursor in a synthesis method through a hot-injection method. However, since the benzoyl halide in the documents was used in a high-temperature environment in the presence of excess carboxylic acid, it was confirmed that the benzoyl halide was consumed for the purpose of synthesizing a halide perovskite nanocrystal, and not remained as a ligand. However, in the present invention, since an acyl halide is used as a ligand in the halide perovskite nanocrystal that has undergone a purification process after high-temperature synthesis or in a low-temperature synthesis environment, it may remain bound to the surface of the finally manufactured halide perovskite nanocrystal particles as a ligand.

### Method of Manufacturing Perovskite Nanocrystal Particles Using Ligand-Assisted Reprecipitation Method and Surface-Treating with Acyl Halide

Meanwhile, as a step of manufacturing the halide perovskite nanocrystal, a manufacturing method of halide perovskite nanocrystal particles using a ligand-assisted reprecipitation method and a method of surface-treating and ligand-substituting the nanocrystal particles with an acyl halide are described.

The manufacturing method may include: a step of preparing solution A containing a halide perovskite precursor dissolved in a polar solvent and solution B containing a ligand dissolved in a nonpolar solvent; and a step of mixing solution A with solution B to form nanocrystal particles.

First, the step of preparing solution A containing a halide perovskite dissolved in a polar solvent is described.

The perovskite precursor is a material constituting an ABX3 crystal forming a perovskite nanocrystal, wherein A may be a monovalent organic cation or a monovalent inorganic cation, B may be a divalent metal ion, and X may be F—, Cl—, Br—, I—, SCN—, OCN—, SeCN—, HCO2—, CH3COO—, or a combination thereof.

The polar solvent is a solvent capable of dissolving a halide perovskite precursor and may be selected from dimethylformamide, dimethyl sulfoxide, acetonitrile, gamma butyrolactone, methylpyrrolidone, and isopropyl alcohol, but is not limited thereto.

Next, the step of preparing solution B containing a ligand dissolved in a nonpolar solvent is described.

At this time, the nonpolar solvent may include dichloroethylene, trichloroethylene, chloroform, chlorobenzene, dichlorobenzene, styrene, dimethylformamide, dimethyl sulfoxide, xylene, toluene, hexane, octadecene, cyclohexene, and isopropyl alcohol, but is not limited thereto.

The ligand may include an alkyl halide, an amine ligand, a carboxylic acid, and a phosphonic acid. Specific descriptions of the alkyl halide, the amine ligand, the carboxylic acid, and the phosphonic acid are the same as described above.

Next, solution A is mixed with solution B to form nanocrystal particles.

The step of mixing solution A with solution B to form nanocrystal particles is preferably performed by dropping solution A into solution B and mixing them. At this time, it is preferable to drop solution A in fine drops and mix, and it is preferable to allow solution A to react by dropping several fine drops from a spray or nozzle. In some cases, solution A in a beaker may be poured as is and dropped into solution B that is being stirred. In addition, solution B at this time may be stirred. In this case, when solution A is dropped into solution B and mixed, a halide perovskite is precipitated from solution B due to the solubility difference. Subsequent surface treatment and ligand substitution using an acyl halide may be performed by purifying a perovskite nanocrystal and then injecting an additive solution containing an acyl halide into the nanocrystal to surface-treat or ligand-substitute the nanocrystal with the acyl halide, and specific details are the same as described above and thus are omitted.

### Method of Manufacturing Perovskite Nanocrystal Particles in situ and Surface-Treating with an Acyl Halide

Next, an in-situ method of manufacturing halide perovskite nanocrystal particles is described.

The manufacturing method includes: a step of preparing a metal halide perovskite precursor solution by dissolving a halide perovskite precursor in a solvent; and a step of applying the halide perovskite precursor solution on a substrate and performing heat treatment to crystallize it.

First, the step of preparing a halide perovskite precursor solution by dissolving the perovskite precursor in a solvent is described.

The perovskite precursor is a material constituting an ABX3 crystal forming a perovskite nanocrystal, wherein A may be a monovalent organic cation or a monovalent inorganic cation, B may be a divalent metal ion, and X may be F—, Cl—, Br—, I—, SCN—, OCN—, SeCN—, HCO2—, CH3COO—, or a combination thereof.

The solvent is a solvent capable of dissolving a halide perovskite precursor and may be selected from dimethylformamide, dimethyl sulfoxide, acetonitrile, gamma butyrolactone, methylpyrrolidone, and isopropyl alcohol, but is not limited thereto.

Thereafter, the step of applying the precursor solution on a substrate and performing heat treatment to crystallize it is performed.

The application method may be selected from the group consisting of spin coating, bar coating, nozzle printing, spray coating, slot die coating, gravure printing, ink jet printing, screen printing, electrohydrodynamic jet printing, and electrospraying, but is not limited thereto.

The heat treatment may be performed at 60 to 80° C. for 5 to 15 minutes.

During the application process and heat treatment process, the solvent is removed, and the halide perovskite precursor is crystallized on the substrate, thereby forming in-situ halide perovskite nanocrystal particles.

The specific details on the preparation of the additive solution containing an acyl halide and a ligand are the same as described above and thus are omitted.

As a surface treatment step using an acyl halide, an additive solution containing an acyl halide and a ligand is applied to the in-situ perovskite nanocrystal particles to perform coating. The specific details of the application method are the same as described above and thus are omitted.

In addition, according to another embodiment of the present invention, the additive solution containing an acyl halide is not limited to simply being used for surface treatment of perovskite nanocrystal particles but it may also be applied as a component of a separate passivation layer or interfacial layer.

For example, by spin-coating a solution containing an acyl halide on a hole transport layer to form a thin acyl halide layer, and then forming a perovskite nanocrystal thin film thereon, the defect state of a lower interface can be reduced, and the crystal growth of an emission layer can be induced.

On the other hand, after forming a perovskite nanocrystal thin film, a solution containing an acyl halide may be applied on the thin film to form a passivation layer on an upper interface, and thus it is possible to suppress interfacial defects with an upper charge transport layer and improve device stability.

Such an acyl halide-based passivation layer can be easily formed through a spin-coating, dip-coating, or printing process, and its chemical stability can be increased through a subsequent process such as heat treatment or ultraviolet irradiation.

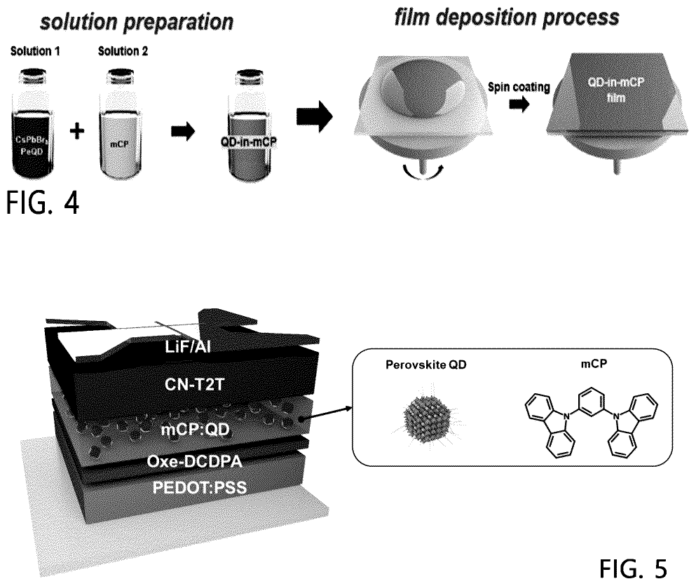

Next, a step of mixing a first solution containing halide perovskite nanocrystals manufactured in the above-described second preliminary step and a second solution containing an organic host for suppressing energy transfer and electronic coupling between the halide perovskite nanocrystals and manufacturing emitters is described. This process is illustrated in FIG. 4.

As a solvent of the above-described first solution, any solvent may be used without limitation as long as it is capable of dissolving a halide perovskite nanocrystal. Preferably, it may be a hydrophobic solvent such as hexane, chloroform, chlorobenzene, toluene, xylene, and cyclohexane, and most preferably, toluene.

In addition, the halide perovskite nanocrystal may be contained in the above-described first solution in an amount of 0.1 to 20 parts by weight based on 100 parts by weight of the solvent of the first solution.

Next, as a solvent of the above-described second solution, any solvent may be used without limitation as long as it is capable of dissolving an organic host. Preferably, it may be a hydrophobic solvent such as hexane, chloroform, chlorobenzene, toluene, xylene, and cyclohexane, and most preferably, toluene.

In addition, the organic host may be contained in the above-described fourth solution in an amount of 0.1 to 20 parts by weight based on 100 parts by weight of the solvent of the second solution.

In addition, the organic host contained in the above-described second solution may have a HOMO energy level of −6.0 eV or less. When the HOMO energy level exceeds −6.0 eV, emitters including the organic host may form an exciplex in relation to an electron transport layer. Referring to FIG. 11C, the organic hosts mCP, CBP, and DCzPPy having a HOMO energy level of −6.0 eV or lower according to an embodiment of the present invention did not exhibit exciplex emission but the organic host TCTA having a HOMO energy level exceeding −6.0 eV exhibited exciplex emission.

The above-described organic host may be a carbazole derivative. Examples of the carbazole derivative include mCP, PCPPn, PCPN, CBP, CzTP, TCPB, and CzPA.

Preferably, the organic host may be a carbazole derivative having a HOMO energy level of −6.0 eV or lower. This has a better exciplex formation prevention effect. Examples of carbazole derivatives having a HOMO energy level of −6.0 eV or lower include SimCP, mCBP, mCP, CBP, and DCzPPy. More preferably, it may be mCP, CBP, and DCzPPy, and the organic hosts are represented by Chemical Formulas 2 to 4, respectively. Most preferably, it may be mCP.

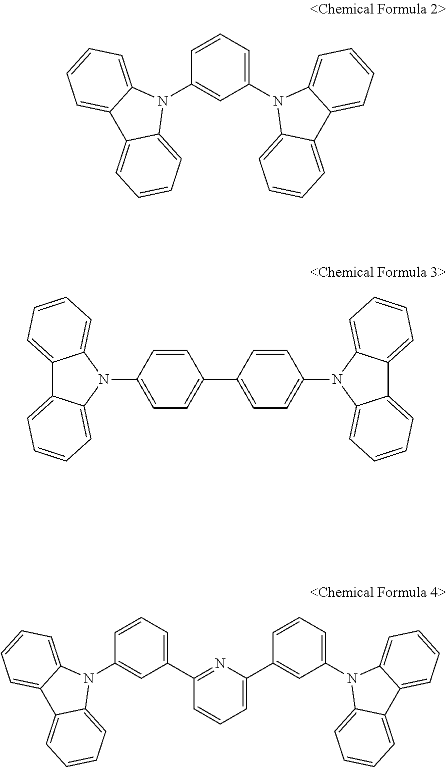 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

Meanwhile, when the above-described first solution and second solution are mixed, 1 to 60 parts by weight of the above-described nanocrystal may be mixed based on 100 parts by weight of the above-described organic host. Preferably, 5 to 30 parts by weight may be mixed. More preferably, 10 to 20 parts by weight may be mixed. More specifically, it may include a range in which the lower value of two numbers among 1, 2, 3, 4, 5, 6, 7, 8, 9, 10, 10.5, 11, 11.5, 12, 12.5, 13, 13.5, 14, 14.5, 15, 15.5, 16, 16.5, 17, 17.5, 18, 18.5, 19, 19.5, 20, 25, 30, 35, 40, 45, 50, 55, and 60 parts by weight is a lower limit and the higher value is an upper limit. When the amount of nanocrystals is less than 1 part by weight, a problem of low efficiency may occur due to insufficient energy transfer from the organic host, and when the amount of nanocrystals exceeds 60 parts by weight, a problem may occur in which the nanocrystals may not be separated from each other by a sufficient distance within the emitters, and thus a red shift may not be effectively prevented.

Next, a method of manufacturing halide perovskite nanocrystal particle emitters by applying a coating solution containing the above-described halide perovskite nanocrystal particles and an organic host is described.

Referring to FIG. 4, any method may be applied to the above-described coating without limitation as long as it is a method of forming emitters using a typical coating solution for emitters, and therefore, the present invention does not specifically limit the method. Preferably, the above- described coating may be spin coating, bar coating, spray coating, slot die coating, gravure coating, blade coating, screen printing, nozzle printing, inkjet printing, electrohydrodynamic jet printing, electrospraying, or electrospinning. Most preferably, the above-described coating may be spin coating.

In addition, when the above-described coating is coating performed by using a spin coating method, any rotational speed during spin coating may be applied without limitation as long as it is a speed that may be commonly used in the art, and therefore the present invention does not specifically limit it, but preferably, it may be in the range of 500 to 6000 rpm.

Furthermore, the halide perovskite nanocrystal particle emitters formed by the above-described coating may have a thickness of 10 to 100 nm.

However, the above-described coating is a type of solution process and not a deposition process. In other words, blue-emitting halide perovskite nanocrystals and emitters including the same may not be formed by a deposition process such as electron beam deposition, thermal evaporation, sputter deposition, atomic layer deposition, or chemical vapor deposition due to the difficulty in controlling the size of the halide perovskite.

The above-described method of manufacturing halide perovskite nanocrystal emitters may further include a step of performing heat treatment after the step of manufacturing the emitters by applying the above-described emitter coating solution. The above-described step of performing heat treatment is for removing a residual solvent in the emitters.

As a heat treatment temperature of the above-described step of performing heat treatment, any temperature may be applied without limitation as long as it is a temperature at which the residual solvent may be removed, and thus the present invention does not specifically limit it, but preferably, it may be 50 to 60° C. Since the halide perovskite nanocrystals included in the above-described emitters should not be damaged during the heat treatment for removing the residual solvent and the temperature should be lower than the glass transition temperature of the organic host, it may be preferable to perform heat treatment within the above-described temperature range.

In order to solve the above-described problem, there is provided a perovskite light-emitting device, which is selected from the group consisting of a light-emitting diode, a light-emitting transistor, a laser, and a polarized light-emitting device including the above-described halide perovskite nanocrystal particles or the above-described halide perovskite nanocrystal particle emitters.

Preferably, the light-emitting device may be an organic/inorganic light-emitting diode and may be operated by a principle of electrically driving using the injection of electrons and holes, through a combination of the balance of electron and hole mobility of each layer and the emission characteristics of the emitters.

Referring to FIG. 5, the above-described light-emitting device may include a substrate, a positive electrode, a hole injection layer, a hole transport layer, an emission layer, an electron transport layer, and a negative electrode. Specifically, the above-described light-emitting device may be formed by laminating in the order of substrate/positive electrode/hole injection layer/hole transport layer/emission layer/electron transport layer/negative electrode. In other words, the light-emitting device may include a substrate, a positive electrode formed on the substrate, a hole injection layer formed on the positive electrode, a hole transport layer formed on the hole injection layer, a halide perovskite nanocrystal particle emission layer formed on the hole transport layer, an electron transport layer formed on the emission layer, and a negative electrode positioned on the electron transport layer.

First, the substrate is a support for the light-emitting device and may be formed of a transparent material or a flexible material. Specifically, the substrate may be glass, polycarbonate (PC), polyethylene terephthalate (PET), polyethylene naphthalate (PEN), polyimide (PI), polypropylene (PP), or a metal substrate, but is not limited thereto. Preferably, it may be glass.

The above-described positive electrode may be formed on the substrate.

The above-described positive electrode may include a conductive material. Specifically, the above-described positive electrode may be indium tin oxide (ITO), fluorine tin oxide (FTO), antimony tin oxide (ATO), tin oxide (SnO2), zinc oxide (ZnO), a metal, a metal alloy, a carbon material, or a conductive polymer such as poly(3-methylthiophene), poly(3,4-(ethylene-1,2-dioxy)thiophene) (polyehtylenedioxythiophene: PEDT), polypyrrole, and polyaniline, but is not limited thereto. Preferably, it may be ITO.

In addition, the above-described positive electrode may have a thickness of 1 to 1000 nm.

The above-described hole injection layer may be formed on the above-described positive electrode.

The above-described hole injection layer may include a hole injection material. For example, the hole injection layer may include one or more of a metal oxide and a hole injection organic material. The metal oxide may include at least one metal oxide selected from the group consisting of MoO3, WO3, V205, nickel oxide (NiO), copper (II) oxide (CuO), copper aluminum oxide (CAO, CuAlO2), zinc rhodium oxide (ZRO, ZnRh2O4), GaSnO, and GaSnO doped with a metal sulfide (FeS, ZnS or CuS). The hole injection organic material may include at least one selected from the group consisting of fullerene (C60), 1,4,5,8,9,11-hexaazatriphenylenchexacarbonitrile (HAT-CN), copper hexadecafluorophthalocyanine (F16CuPC), copper phthalocyanine (CuPC), 4,4′,4″-tris(3-methylphenylphenylamino)triphenylamine (m-MTDATA), N,N′-di (1-naphthyl)-N,N′-diphenyl-(1,1′-biphenyl)-4,4′-diamine) (NPB), 4,4′,4′-tris(N,N-diphenylamino)triphenylamine (TDATA), 4,4′,4″-tris(N-(naphthalen-2-yl)-N-phenyl-amino)-triphenylamine (2T-NATA), polyaniline/dodecylbenzenesulfonic acid (PANI/DBSA), poly(3,4-ethylenedioxythiophene)/poly(4-styrenesulfonate) (PEDOT:PSS), polyaniline/camphorsulfonic acid (PANI/CSA), and polyaniline/poly(4-styrenesulfonate) (PANI/PSS), but is not limited thereto. Preferably, it may be PEDOT:PSS.

In addition, the above-described hole injection layer may have a thickness of 1 to 1000 nm.

The above-described hole transport layer may be at least one selected from poly(9-vinylcarbazole) (PVK), poly(4-butylphenyl-diphenyl-amine) (Poly-TPD), poly(p-phenylene sulfide), poly(p-phenylene vinylene) (PPV), poly (3-methylthiophene), polypyrrole, 4,4′-cyclohexylidenebis[N,N-bis(4-methylphenyl)benzenamine] (TAPC), (4,4′-Bis(N-carbazolyl)-1,1′-biphenyl) (CBP), amorphous 4,4′-bis (ncarbazolyl)-1,1′-biphenyl (mCBP), 2,2′,7,7′-tetrakis[N,N-di(4-methoxyphenyl)amino]-9,9′-spirobifluorene (spiro-OMeTAD), 3,5-di-9H-carbazol-9-yl-N,N-bis[4-[[6-[(3-ethyl-3-oxetanyl)methoxy]hexyl]oxy]phenyl]benzenamine (Oxe-DCDPA), and a p-type metal oxide, but is not limited thereto. Preferably, it may be Oxe-DCDPA

In addition, the above-described hole transport layer may have a thickness of 1 to 1000 nm.

The above-described halide perovskite nanocrystal particle emitters may be formed on the above-described hole transport layer and include an organic host and halide perovskite nanocrystal particles. The above-described emitters are a mixture containing the above-described organic host, which is capable of suppressing energy transfer and electronic coupling between the above-described halide perovskite nanocrystal particles. Specific details of the emitters are the same as described above, and thus the details are omitted.

A light-emitting device employing the above-described emitters may have improved emission efficiency and emit deep blue light. Accordingly, a light-emitting device including the emitters has an emission spectrum peak at 420 to 467 nm and thus is capable of emitting deep blue light.

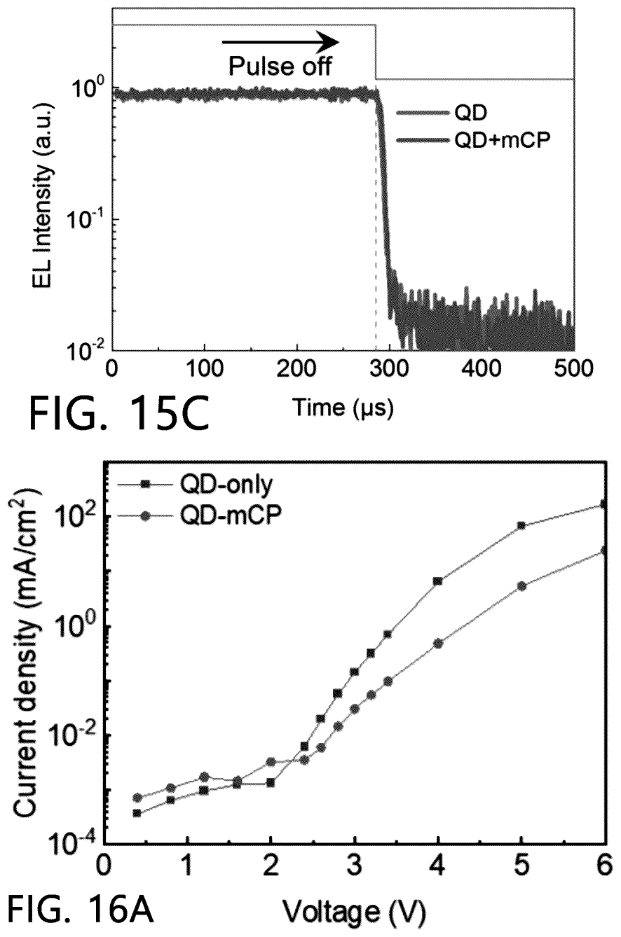

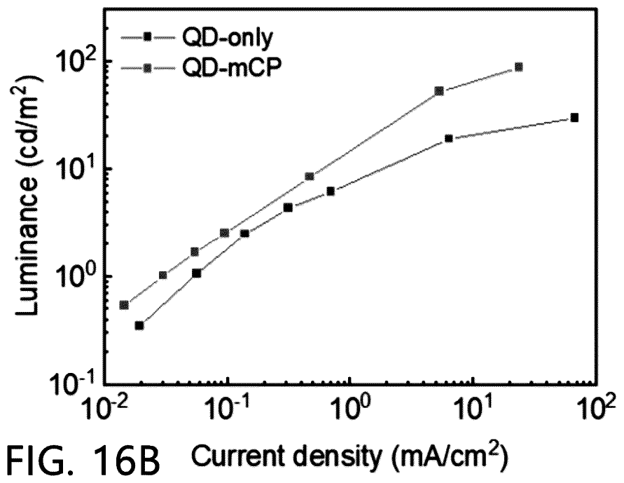

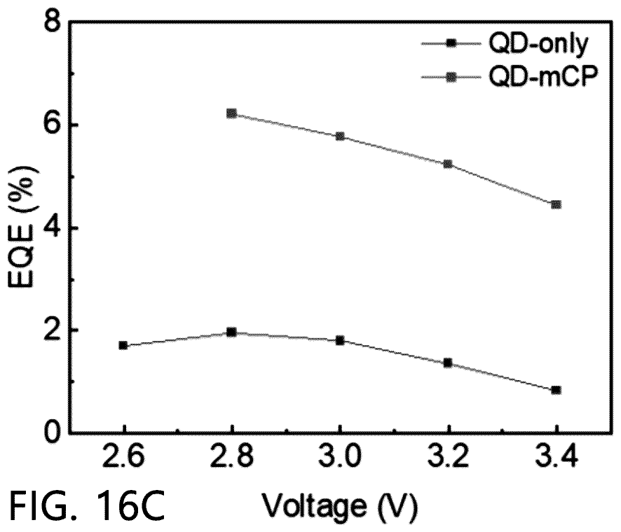

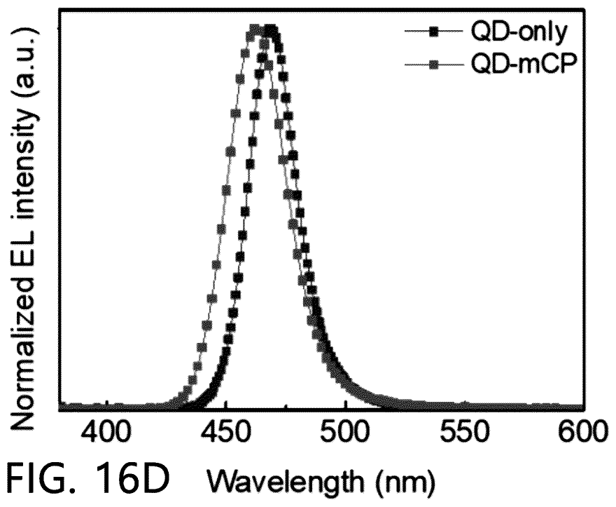

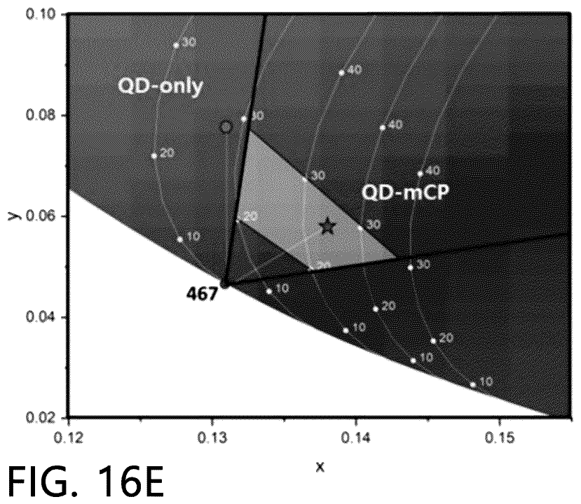

Specifically, referring to FIGS. 16A to 16C, it can be confirmed that a light-emitting device including the above-described halide perovskite nanocrystal particle emitters has a similar current density but exhibits higher emission intensity and higher external quantum efficiency (EQE) compared to a light-emitting device including halide perovskite nanocrystal particle emitters not including an organic host. In addition, referring to FIGS. 16D and 16E, it can be confirmed that a light-emitting device including the above-described emitters emits deep blue light unlike a light-emitting device not including an organic host.

The above-described electron transport layer may be formed on the above-described emitters. Specifically, the above-described electron transport layer may be one or more selected from 2,4,6-tris[3-(diphenylphosphoryl)phenyl]-1,3,5-triazine (CN-T2T) (see Chemical Formula 5 below), bis-4,6-(3,5-di-3-pyridylphenyl)-2-methylpyrimidine (B3PYMPM), 2,2′,2″-(1,3,5-benzenetriyl)tris-[1-phenyl-1H-benzimidazole] (TPBi), tris(8-quinolinolate) aluminum (Alq3), perfluorinated compound (PF-6P), 4,7-diphenyl-1,10-phenanthroline (Bphen), diphenylphosphineoxide-4-(triphenylsilyl) phenyl (TSPO1), and 1,3,5-tri (N-phenylbenzimidazol-2-yl)benzene (TPBI), and a metal oxide including ZnO, TiO2, SnO, SrTiO3, BaTiO3, and the like, but is not limited to thereto. Preferably, it may be CN-T2T.

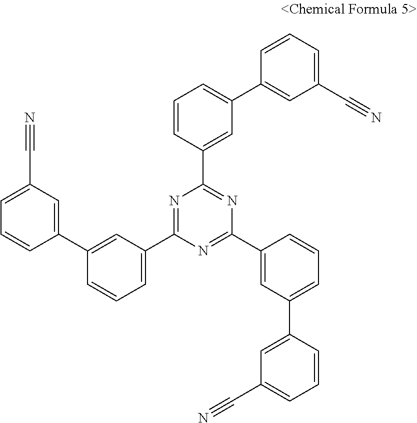 [SMILES: N#Cc1cccc(-c2cccc(-c3nc(-c4cccc(-c5cccc(C#N)c5)c4)nc(-c4cccc(-c5cccc(C#N)c5)c4)n3)c2)c1]

In addition, the above-described electron transport layer may have a thickness of 1 to 1000 nm.

The above-described negative electrode may be formed on the above-described electron transport layer.

Specifically, the above-described negative electrode may be a metal such as magnesium (Mg), calcium (Ca), sodium (Na), potassium (K), titanium (Ti), indium (In), yttrium (Y), lithium (Li), gadolinium (Gd), aluminum (Al), silver (Ag), tin (Sn), lead (Pb), cesium (Cs), or barium (Ba), or an alloy thereof, or may be a multilayer structure material such as LiF/Al, LiO2/Al, LiF/Ca, LiF/Al, and BaF2/Ca, but is not limited thereto. Preferably, it may be LiF/Al.

In addition, the above-described negative electrode may have a thickness of 1 to 1000 nm.

Meanwhile, a method of manufacturing the above-described light-emitting device may include: a step of forming the above-described positive electrode on the above-described substrate; a step of forming the above-described hole injection layer on the above-described positive electrode; a step of forming the above-described hole transport layer on the above-described hole injection layer; a step of forming the above-described halide perovskite nanocrystal particle emitters on the above-described hole transport layer; a step of forming the above-described electron transport layer on the above-described halide perovskite nanocrystal particle emitters; and a step of forming the above-described negative electrode on the above-described electron transport layer.

First, the step of forming the above-described halide perovskite nanocrystal particle emitters may utilize the above-described method of manufacturing halide perovskite nanocrystal particle emitters.

The process of forming the above-described positive electrode, hole transport layer, electron transport layer, and negative electrode may be performed using a conventional light-emitting device manufacturing method. Specifically, when forming the above-described positive electrode, hole transport layer, electron transport layer, and negative electrode, a solution process, a deposition process, an atomic layer deposition (ALD) process, or a chemical vapor deposition (CVD) process may be applied, but the process is not limited thereto. Preferably, each layer may be formed by a CVD process, a solution process, or a deposition process. More preferably, the positive electrode may be formed by a CVD process, the hole transport layer may be formed by a solution process, and the electron transport layer and the negative electrode may be formed by a deposition process.

The present invention will be described more specifically through the following examples but the following examples do not limit the scope of the present invention and should be interpreted as helping to understand the present invention.

### PREPARATION EXAMPLES

### Preparation Example 1—Halide Perovskite Nanocrystal (blue)

### <Synthesis Process>

325.8 mg of a Cs2CO3 precursor was dissolved in 9 mL of 1-octadecene with 0.7 mL of oleic acid at 120° C. under vacuum to prepare 9.7 mL of Cs-oleate solution.

225 mg of a PbBr2 precursor and 552 mg of a ZnBr2 precursor were dissolved in 15 mL of 1-octadecene with 6 mL of oleylamine and oleic acid as ligands at 120° C. under vacuum to prepare 27 mL of PbBr2 solution. Thereafter, 2 mL of the Cs-oleate solution was injected into the 27 mL of the PbBr2 solution at 90° C. to generate a reaction product. After 30 seconds of reaction time, the reaction product was quenched in ice water to lower the temperature, thereby preparing a halide perovskite nanocrystal.

### <Purification Process>

27 mL of the solution containing the synthesized CsPbBr3 nanocrystal dispersed in 1-octadecene was added to 54 mL of methyl acetate to coagulate, and then the coagulated product was settled using a centrifuge at a rotational speed of 6000 rpm. Thereafter, the supernatant was removed, and the settled CsPbBr3 nanocrystals were redispersed in 2 mL of hexane. The nanocrystals were coagulated using 8 mL of methyl acetate and extracted using a centrifuge at a rotational speed of 12000 rpm, and the settled nanocrystals were redispersed in toluene.

### Preparation Example 2—Halide Perovskite Nanocrystal (Green)

Green halide perovskite nanocrystal particles were prepared in the same manner as in Preparation Example 1, except that the Cs-oleate solution was injected into the PbBr2 solution at 180° C. to generate a reaction product.

### Preparation Example 3—Halide Perovskite Nanocrystal (Red)

225 mg of a PbI2 precursor and 552 mg of a ZnI2 precursor were dissolved in 15 mL of 1-octadecene with 6 mL of oleylamine and oleic acid as ligands under vacuum at 120° C. to prepare 27 mL of PbI2 solution. Thereafter, red halide perovskite nanocrystal particles were prepared in the same manner as in Preparation Example 1, except that a Cs-oleate solution was injected into the PbI2 solution at 180° C. to generate a reaction product.

### EXAMPLES

### Example 1—Halide Perovskite Nanocrystal Particles Surface-Treated with Benzoyl Bromide and Phenethyl Amine

The nanocrystal was surface-treated by injecting 20 μL of an additive solution containing 5 μL of benzoyl bromide and 5 μL of phenethylamine dissolved in 1 mL of toluene into a solution of CsPbBr3 nanocrystals dispersed in 1 mL of toluene and allowing the resulting mixture to react for ten minutes. The above-described purification process was performed once more on the surface-treated CsPbBr3 nanocrystals, and the purified nanocrystals were dispersed in 1 mL of toluene.

### Example 2—Halide Perovskite Nanocrystal Particles Surface-Treated with Acetyl Bromide and Aniline

Halide perovskite nanocrystal particles were prepared in the same manner as in Example 1, except that an additive solution containing acetyl bromide and aniline instead of benzoyl bromide and phenethylamine was used.

### Example 3—Halide Perovskite Nanocrystal Particles Surface-Treated with Propionyl bromide and Benzyl Amine

Halide perovskite nanocrystal particles were prepared in the same manner as in Example 1, except that an additive solution containing propionyl bromide and benzyl amine instead of benzoyl bromide and phenethylamine was used.

### Example 4—Halide Perovskite Nanocrystal Particles Surface-Treated with Valeryl Bromide and 3-phenyl-1-propylamine

Halide perovskite nanocrystal particles were prepared in the same manner as in Example 1, except that an additive solution containing valeryl bromide and 3-phenyl-1-propylamine instead of benzoyl bromide and phenethylamine was used.

### COMPARATIVE EXAMPLES

### Comparative Example 1—Non-Surface-Treated Halide Perovskite Nanocrystal Particles

Halide perovskite nanocrystal particles were prepared in the same manner as in Example 1, except that no additive solution was added to the solution containing CsPbBr3 nanocrystals dispersed in 1 mL of toluene.

### EXPERIMENTAL EXAMPLES

Experimental Example 1: Transmission Electron Microscope (TEM) Analysis of Halide Perovskite Nanocrystal

TEM images of the halide perovskite nanocrystal of Preparation Example 1 were obtained using transmission electron microscope (Themis Z) equipment.

Referring to FIG. 6, it was confirmed that nanocrystals having a uniform size were synthesized, and it was confirmed that the average particle size of the nanocrystals was 4 nm. It was confirmed in Experimental Example 3 to be described below that the average particle size of CsPbBr3 nanocrystals was 5.5 nm or less, and therefore, they emitted blue light.

### Experimental Example 2: Emission Spectrum and Absorption Spectrum of Halide Perovskite Nanocrystal

The emission spectrum was measured by a steady-state photoluminescence measurement method using a spectrofluorometer (Jasco, FP-8250), and the absorption spectrum was measured by measuring the absorbance of the nanocrystal in a solution state contained in a cuvette using a UV/vis spectrophotometer (PerkinElmer, Lambda 465). The emission spectra of Examples 1, 2, 3, and 4 were measured, and the results are shown in FIGS. 7A, 8, and 13A. In addition, the emission spectrum of Comparative Example 1 was measured, and the results are shown in FIG. 7A. In addition, the absorption spectrum of Example 1 was measured, and the results are shown in FIGS. 8 and 13A.

Referring to FIG. 7A, it can be confirmed that the emission intensity of the surface-treated nanocrystal (Examples 1, 2, 3, and 4) was higher than that of the non-surface-treated nanocrystal (Comparative Example 1). This is because surface-treatment of the nanocrystal can effectively mix the nanocrystals into the coating solution, uniformly disperse the nanocrystals in the coating solution, and ultimately increase the emission intensity and photoluminescence quantum efficiency of the nanocrystals.

### Experimental Example 3: Photoluminescence Quantum Efficiency of Halide Perovskite Nanocrystal

The photoluminescence quantum efficiency was analyzed by measuring steady-state photoluminescence using a spectrofluorometer (Jasco, FP-8250) and then calculating the ratio of the intensity of emitted light to the intensity of absorbed light. The photoluminescence quantum efficiency of Examples 1, 2, 3, and 4, and Comparative Example 1 were measured, and the results are shown in FIG. 7B.

Referring to FIG. 7B, it can be confirmed that the photoluminescence quantum efficiency of the surface-treated nanocrystals (Examples 1, 2, 3, and 4) was higher than that of the non-surface-treated nanocrystal (Comparative Example 1). This is because defects causing non-radiative recombination were controlled during the surface treatment process.

### Experimental Example 4: Fourier Transform Infrared (FT-IR) Spectrum

The FT-IR spectrum was measured for a solid-state nanocrystal using an FT-IR spectrometer (Thermo Fisher Scientific, Nicolet iS50) in the attenuated total reflectance (ATR) mode. The FT-IR spectra of Example 1 and Comparative Example 1 were measured, and the results are shown in FIG. 7C.

Referring to FIG. 7C, it can be seen that the alkyl group-based ligand was reduced in the surface-treated nanocrystal (Example 1) compared to the non-surface-treated nanocrystal (Comparative Example 1). This is because during the surface treatment process, benzoyl bromide and phenethyl amine replaced oleylamine and oleic acid that were used in the synthesis. This indicates that the electrical characteristics of the surface-treated nanocrystal were improved.

### EXAMPLES

### Example 5—Benzoyl Bromide and Phenethyl Amine-Treated Halide Perovskite Nanocrystal Particles Prepared by Ligand-Assisted Reprecipitation

Solution A was prepared by dissolving a halide perovskite precursor in a polar solvent. At this time, dimethyl sulfoxide was used as the polar solvent, and CH(NH2)2PbBr3 was used as the halide perovskite precursor. In the CH(NH2)2PbBr3 used at this time, CH(NH2)2Br and PbBr2 was mixed in a ratio of 1.2:1, and CH(NH2)2PbBr3 was mixed in an amount of 10 parts by weight based on 100 parts by weight of the total amount of solution A.

Solution B was prepared by dissolving decyl amine and oleic acid in a nonpolar solvent. At this time, toluene was used as the nonpolar solvent, and a mixture of decyl amine (20 μL) and oleic acid (200 μL) in 5 mL of toluene was used.

150 μL of solution A was injected into solution B, and the resulting mixture was stirred for ten minutes to synthesize halide perovskite nanocrystal particles using the ligand-assisted reprecipitation method.

Next, the synthesized nanocrystal particles were settled using a centrifuge at a rotational speed of 12,000 rpm, and the supernatant was removed. The settled nanocrystals were redispersed in 2 ml of toluene and then coagulated using 8 ml of methyl acetate. The coagulated product was extracted using a centrifuge at a rotational speed of 12,000 rpm, and the settled nanocrystals were redispersed in 1 ml of toluene.

Surface treatment of the nanocrystal was performed by injecting 20 μL of an additive solution containing 5 μL of benzoyl bromide and 5 μL of phenethyl amine dissolved in 1 mL of toluene into a solution of perovskite nanocrystals dispersed in 1 mL of toluene and allowing the resulting mixture to react for ten minutes. The above-described purification process was performed once more on the surface-treated perovskite nanocrystals, and the purified nanocrystals were dispersed in 1 mL of toluene.

### Example 6—In-situ Halide Perovskite Nanocrystal Particles Surface-Treated with Benzoyl Bromide and Phenethyl Amine

Solution A was prepared by dissolving a halide perovskite precursor in a polar solvent. At this time, dimethyl sulfoxide was used as the polar solvent, and CH3NH3PbBr3 was used as the halide perovskite precursor. In the CH3NH3PbBr3 used at this time, CH3NH3Br and PbBr2 was mixed in a ratio of 1.06:1, and CH3NH3PbBr3 was mixed in an amount of 35 parts by weight based on the total amount of solution A (to achieve 1.2 M).

After applying solution B onto a glass substrate, spin coating was performed while rotating the glass substrate at a speed of 3000 rpm to manufacture a thin film, and the manufactured thin film was heat-treated at 90° C. for ten minutes to manufacture in-situ perovskite nanocrystal particles.

Next, 150 μL of an additive solution containing 5 μL of benzoyl bromide and 5 μL of phenethyl amine dissolved in 1 mL of toluene was applied to the in-situ perovskite nanocrystal particles, and spin coating was performed while rotating at a speed of 3000 rpm to manufacture surface-treated in-situ perovskite nanocrystal particles.

### EXAMPLES

### Example 7—Halide Perovskite Nanocrystal Particle Emitters including Benzoyl Bromide and Phenethyl Amine-Based Lower Passivation Layer

20 μL of an additive solution containing 5 μL of benzoyl bromide and 5 μL of phenethyl amine dissolved in 1 mL of toluene was applied onto the hole transport layer, and spin coating was performed at a rotational speed of 3000 rpm to prepare a passivation layer.

50 μL of a CsPbBr3 nanoparticle solution was applied onto the passivation layer, spin coating was performed at a rotational speed of 3000 rpm, and heat-treatment was performed at 90° C. for ten minutes to manufacture halide perovskite nanocrystal particle emitters.

### Example 8—Halide Perovskite Nanocrystal Particle Emitters Including Benzoyl Bromide and Phenethyl Amine-Based Upper Passivation Layer

50 μL of a CsPbBr3 nanoparticle solution was applied, spin coating was performed at a rotational speed of 3000 rpm, and heat treatment was performed at 90° C. for ten minutes to manufacture halide perovskite nanocrystal particle emitters.

20 μL of an additive solution containing 5 μL of benzoyl bromide and 5 μL of phenethyl amine dissolved in 1 mL of methyl acetate was applied onto the nanocrystal particle emitters, and spin coating was performed at a rotational speed of 3000 rpm to prepare an upper passivation layer.

### Example 9

5 mg of the halide perovskite nanocrystal particles of Example 1 were dispersed in 1 mL of toluene to form a nanocrystal solution, and 5 mg of an organic host (mCP) was dissolved in 1 mL of toluene to form an organic host (mCP) solution. Thereafter, 5 μL of the nanocrystal solution and 495 μL of the organic host (mCP) solution were mixed to prepare a coating solution for emitters.

By using the coating solution and performing spin coating at a speed of 3000 rpm, thin film-shaped halide perovskite nanocrystal particle emitters (thickness: 30 nm) were formed on the hole transport layer.

Thereafter, heat treatment was performed at 60° C. for five minutes to remove the residual solvent in the formed emitters.

### Example 10

Emitters were manufactured in the same manner as in Example 9, except that 25 μL of the nanocrystal solution and 475 μL of the organic host (mCP) solution were mixed.

### Example 11

Emitters were manufactured in the same manner as in Example 9, except that 50 μL of the nanocrystal solution and 450 μL of the organic host (mCP) solution were mixed.

### Example 12

Emitters were manufactured in the same manner as in Example 9, except that 75 μL of the nanocrystal solution and 425 μL of the organic host (mCP) solution were mixed.

### Example 13

Emitters were manufactured in the same manner as in Example 9, except that 100 μL of the nanocrystal solution and 400 μL of the organic host (mCP) solution were mixed.

### Example 14

Emitters were manufactured in the same manner as in Example 9, except that 150 μL of the nanocrystal solution and 350 μL of the organic host (mCP) solution were mixed.

### Example 15

Emitters were manufactured in the same manner as in Example 9, except that 200 μL of the nanocrystal solution and 300 μL of the organic host (mCP) solution were mixed.

### Example 16

Emitters were manufactured in the same manner as in Example 9, except that 250 μL of the nanocrystal solution and 250 μL of the organic host (mCP) solution were mixed.

### Example 17

Emitters were manufactured in the same manner as in Example 9, except that 300 μL of the nanocrystal solution and 200 μL of the organic host (mCP) solution were mixed.

TABLE 3

| | Nanocrystal | | Organic host | Nanocrystal:mCP |
|---|---|---|---|---|
| | solution | | solution | (parts by weight) |
| Example 9 | 5 | μl | 495 μl | 1:99 |
| Example 10 | 25 | μl | 475 μl | 5:95 |
| Example 11 | 50 | μl | 450 μl | 10:90 |
| Example 12 | 75 | μl | 425 μl | 15:85 |
| Example 13 | 100 | μl | 400 μl | 20:80 |
| Example 14 | 150 | μl | 350 μl | 30:70 |
| Example 15 | 200 | μl | 300 μl | 40:60 |
| Example 16 | 250 | μl | 250 μl | 50:50 |
| Example 17 | 300 | μl | 200 μl | 60:40 |

### Example 18

Emitters were manufactured in the same manner as in Example 9, except that 50 μL of the nanocrystal solution and 450 μL of the organic host (CBP) solution were mixed.

### Example 19

Emitters were manufactured in the same manner as in Example 9, except that 50 μL of the nanocrystal solution and 450 μL of the organic host (DCzPPy) solution were mixed.

### Example 20

Emitters were manufactured in the same manner as in Example 9, except that 50 μL of the nanocrystal solution and 450 μL of the organic host (TCTA) solution were mixed.

### COMPARATIVE EXAMPLES

### Comparative Example 2

Emitters were manufactured in the same manner as in Example 9, except that a coating solution for emitters was prepared without mixing an organic host solution.

### Comparative Example 3

Emitters were manufactured in the same manner as in Example 9, except that a coating solution for emitters was prepared without mixing a nanocrystal solution.

TABLE 4

| | Type of | EHOMO | ELUMO |
|---|---|---|---|
| | host | (eV) | (eV) |
| Examples 9-17 | mCP | −6.1 | −2.4 |
| Example 18 | CBP | −6.0 | −2.9 |
| Example 19 | DCzPPy | −6.05 | −2.56 |
| Example 20 | TCTA | −5.83 | −2.43 |

Referring to Table 4, it can be confirmed that the mCP, CBP, and DCzPPy organic hosts have a HOMO energy level of −6.0 eV or less, whereas the TCTA organic host has a HOMO energy level exceeding −6.0 eV. In addition, the organic hosts of each example are expected to have semiconductor properties due to the presence of a band gap, and when the organic hosts are added to emitters, the organic hosts may absorb energy and transfer energy to the halide perovskite nanocrystal, thereby improving the external quantum efficiency of the light-emitting device.

### Experimental Example 5: Emission Spectrum of Halide Perovskite Nanocrystal Emitters

The emission spectrum of the halide perovskite nanocrystal emitters was measured by steady-state photoluminescence measurement using a spectrofluorometer (Jasco, FP-8250). The emission spectra of Examples 9 to 17 and Comparative Example 2 were measured, and the results are shown in FIGS. 12A and 12B.

The average distance between nanocrystals in FIG. 12A was obtained by mathematically dividing the number of nanocrystals in the emitter. As the amount of organic host added to the emitters increases, the average distance between nanocrystals increases, which suppresses energy transfer and electronic coupling between nanocrystals, thereby preventing the spectrum from being red-shifted.

According to FIG. 12B, Comparative Example 2 (denoted as c) shows a red-shifted spectrum due to electronic coupling and energy transfer between nanocrystals because an organic host was not mixed. Example 17 (denoted as b) shows a spectrum shifted to the blue region because an organic host was mixed in an amount of 40% by weight, and electronic coupling was suppressed as the distance increased, and thus a red shift was prevented. Example 11 (denoted as a) shows a spectrum that was most shifted to the blue region because an organic host was mixed in an amount of 90% by weight, and electronic coupling and energy transfer were suppressed as the distance between nanocrystals became sufficiently far. The emitters corresponding to Example 11 (denoted as c) exhibited a wavelength of 465 nm, which was closest to deep blue. The emitters corresponding to Example 17 (denoted as b) exhibited a wavelength of 471 nm, which was red-shifted. The emitters corresponding to Comparative Example 2 (denoted as a) exhibited a wavelength of 473 nm, which was the most red-shifted.

The emission spectrum of Comparative Example 3, which consists only of the organic host mCP, was measured, and the results are shown in FIG. 13A. It can be confirmed that the emission spectrum of Comparative Example 3 overlaps the absorption spectrum of Preparation Example 1, suggesting that when both Preparation Example 1 and the organic host mCP are mixed and included in the emitters, the organic host mCP may transfer energy to the nanocrystal of Preparation Example 1, thereby increasing emission efficiency.

### Experimental Example 6: Absorption Spectrum of Halide Perovskite Nanocrystal Emitters and Tauc Plot based Thereon

The absorption spectrum was measured by transmitting the emitters formed on a glass substrate with a UV/vis spectrophotometer (PerkinElmer, Lambda 465). The Tauc plot based thereon was calculated by mathematically converting the absorbance according to the wavelength using a conversion coefficient. The absorption spectra of Examples 11 and 17 and Comparative Example 2 and the Tauc plots based thereon were measured and calculated, and the results are shown in FIG. 12C.

Referring to FIG. 12C, the intersection of the red dotted line and the x-axis in the graph of FIG. 12C represents the optical band gaps of Example 11, Example 17, and Comparative Example 2. The band gap is small at point a (Comparative Example 2), but the band gap increased about 13 meV at points b (Example 17) and c (Example 11). This is an effect of suppressing electronic coupling.

### Experimental Example 8: Time-Resolved Emission Spectrum of Emitters

The emission spectrum according to the photoluminescence lifetime was measured by simultaneously resolving the emission spectrum and the photoluminescence lifetime using a streak camera. The emission spectrum according to the photoluminescence lifetime range of Example 11 was measured, and the results are shown in FIG. 11A, and the emission spectrum according to the photoluminescence lifetime range of Comparative Example 2 was measured, and the results are shown in FIG. 11B.

Referring to FIGS. 11A and 11B, FIG. 11A shows the results of Example 11, and it can be seen that almost no red shift occurred even when the photoluminescence lifetime increased, whereas FIG. 11B shows the results of Comparative Example 2, and it can be seen that a red shift occurred when the photoluminescence lifetime increased. This is because in Example 11, the distance between nanocrystals was long, and thus there was almost no possibility of energy transfer and electronic coupling between nanocrystals, whereas in Comparative Example 2, the distance between nanocrystals was short, and energy transfer between nanocrystals occurred, which appeared in the form of a red shift in the region where the photoluminescence lifetime was long.

### Experimental Example 9: Time-Resolved Emission Spectrum Map of Emitters and Spectral Peaks Extracted Therefrom

The time-resolved spectrum map was measured by simultaneously resolving the emission spectrum and photoluminescence lifetime with a streak camera, and the spectral peaks extracted from the map were obtained and shown in a graph. The spectrum map and the spectral peaks of Comparative Example 2 were measured and analyzed, and the results are shown in FIG. 12D. Those of Example 17 were measured and analyzed, and the results are shown in FIG. 12E. Those of Example 11 were measured and analyzed, and the results are shown in FIG. 12F.

Referring to FIGS. 12D, 12E, and 12F, the spectrum peak in FIG. 12E (Example 17) was blue-shifted in parallel compared to FIG. 12D (Comparative Example 2), which was a result of suppressing electronic coupling. It can be confirmed that the spectrum was red-shifted over time in FIGS. 12D (Comparative Example 2) and 12E (Example 17), indicating that energy transfer occurred. In FIG. 12F (Example 11), the spectrum did not change over time, which shows that energy transfer was suppressed. In other words, these results suggest that the farther the distance between particles is, the more advantageous it is for suppressing the interaction between nanocrystals to obtain deep blue light.

### Experimental Example 10: Emission Spectrum According to the Excitation Spectrum of Emitters

The emission spectrum according to the excitation spectrum was measured by varying the excitation wavelength using a spectrofluorometer (Jasco, FP-8250) and measuring the emission spectrum. The emission spectrum of Comparative Example 3 was measured, and the results are shown in FIG. 13B. The emission spectrum of Example 11 was measured, and the results are shown in FIG. 13C. The emission spectrum of Comparative Example 2 was measured, and the results are shown in FIG. 13D.

Referring to FIGS. 13A to 13D, the emitters of Example 11 in FIG. 13B exhibited a strong emission spectrum in the 280 to 360 nm excitation spectrum range where the emitters of Comparative Example 3 emit light as shown in FIG. 13A. These results may mean that in Example 11 including an organic host, energy is transferred very efficiently from the organic host to a nanocrystal. In addition, when FIGS. 13D and 13B were compared, it can be confirmed that the emission spectrum of the emitters of Example 11 slightly shifted to a wavelength of 467 nm or less compared to the emitters of Comparative Example 2, and thus energy transfer and electronic coupling were suppressed.

### Experimental Example 11: Time-Resolved Photoluminescence Graph of Emitters

The time-resolved emission graph of the emitters was measured by the time-resolved fluorescence method using a photoluminescence spectrometer (PicoQuant, FlouTime 300).

For Example 11 and Comparative Example 2, the transient emission graph of the nanocrystal according to the presence or absence of an organic host was measured, and the results are shown in FIG. 14A. For Example 11 and Comparative Example 3, the transient emission graph of the organic host according to the presence or absence of nanocrystals was measured, and the results are shown in FIG. 14B.

Referring to FIG. 14A, it can be confirmed that in the case where an organic host was mixed with a halide perovskite nanocrystal as in Example 11, the photoluminescence lifetime increased compared to the case where an organic host was not included as in Comparative Example 2.

Referring to FIG. 14B, it can be confirmed that in the same wavelength range, the photoluminescence lifetime of the mCP of the emitters including both a halide perovskite nanocrystal and the organic host mCP (Example 11) was somewhat reduced compared to the mCP of the emitters (Comparative Example 3) including only the organic host mCP. This may be considered to be due to the mCP serving as an organic host and effectively transferring energy to the halide perovskite nanocrystal.

### MANUFACTURING EXAMPLE

### Manufacturing Example 1—Light-Emitting Device (Including the Emitters of Example 11)

First, ITO-patterned glass with a thickness of 70 nm was successively ultrasonically cleaned in acetone and isopropanol for 15 minutes each, and then UV-ozone-treated for 20 minutes. Thereafter, PEDOT: PSS was spin-coated at a speed of 4000 rpm to form a hole injection layer with a thickness of 30 nm. The coated film was annealed at 120° C. for 10 minutes, and then transferred to a nitrogen-filled glove box for the manufacture of a hole transport layer and emitters. For the hole transport layer, Oxe-DCDPA was dissolved in chlorobenzene at a concentration of 8 mg/mL, spin-coated, and annealed at 120° C. for 10 minutes to form a layer with a thickness of 15 nm. A coating solution containing a mixture of an organic host and nanocrystals was spin-coated on the formed hole transport layer at 1500 rpm to manufacture an emitter film, which was then annealed at 60° C. for five minutes. Thereafter, the sample was transferred to a high-vacuum deposition chamber, and a 45 nm-thick CN-T2T (electron transport layer), a 1 nm-thick LiF layer, and a 100 nm-thick Al layer were sequentially deposited to be used as a negative electrode, thereby completing the fabrication of a light-emitting device.

### Comparative Manufacturing Example 1—Light-Emitting Device (Including the Emitters of Comparative Example 2)

A light-emitting device was manufactured in the same manner as in Manufacturing Example 1, except that when forming emitters, an organic host was not included in the coating solution for emitters.

### Comparative Manufacturing Example 2—Light-Emitting Device (Including the Emitters of Example 18)

A light-emitting device was manufactured in the same manner as in Manufacturing Example 1, except that when forming emitters, CBP, rather than mCP, was used as an organic host in the coating solution for emitters.

### Comparative Manufacturing Example 3—Light-Emitting Device (Including the Emitters of Example 19)

A light-emitting device was manufactured in the same manner as in Manufacturing Example 1, except that when forming emitters, DCzPPy, rather than mCP, was used as an organic host in the coating solution for emitters.

### Comparative Manufacturing Example 4—Light-Emitting Device (Including the Emitters of Example 20)

A light-emitting device was manufactured in the same manner as in Manufacturing Example 1, except that when forming emitters, TCTA, rather than mCP, was used as an organic host in the coating solution for emitters.

### EXPERIMENTAL EXAMPLES

### Experimental Example 12: Graphs Representing the Electroluminescence Spectra Obtained from the Transient Section

Graphs representing the electroluminescence spectra in the transient section were obtained by measuring the electroluminescence over time while applying a pulse-shaped voltage to light-emitting devices using a streak camera. FIGS. 15A, 15B, and 15C shows the results obtained by measuring in the same manner as described above for Manufacturing Example 1 and Comparative Manufacturing Example 1.

FIG. 15A shows a graph of the entire section, FIG. 15B shows a graph of a section where the electroluminescence intensity increased from the beginning of signal application, and FIG. 15C shows a graph of a section where the electroluminescence intensity decreased after the signal application stops.

In FIG. 15A, FIG. 15B, and FIG. 15C, a pulse voltage of 5 ms, 2.9 V, and 20 Hz was applied. Referring to FIG. 15B, it can be confirmed that when the pulse began to be applied, the start of electroluminescence of Manufacturing Example 1 was somewhat delayed compared to Comparative Manufacturing Example 1. This indicates that due to mCP serving as an organic host in the emitters of Manufacturing Example 1, the charge was injected through the organic host mCP instead of being directly injected into the nanocrystal.

In FIG. 15C, when the pulse application was terminated, there was no significant difference in the electroluminescence spectrum according to the presence or absence of the organic host.

### Experimental Example 13: Current Density-Voltage Analysis of Light-Emitting Devices

The current density-voltage graphs of light-emitting devices were analyzed by driving the electronic devices using a sourcemeter (Keithley 236) and a spectroradiometer (Konica Minolta, Cs-2000) that apply and measure voltage and current and measuring the intensity and spectrum of the emitted electroluminescence. Manufacturing Example 1 and Comparative Manufacturing Example 1 were analyzed as described above, and the results are shown in FIG. 16A.

Referring to FIG. 16A, it was confirmed that the current density according to the voltage of Manufacturing Example 1 decreased compared to that of Comparative Manufacturing Example 1.

### Experimental Example 14: Luminance-Current Density Analysis of Light-Emitting Devices

The luminance-current density graphs of light-emitting devices were analyzed by driving the electronic devices using a sourcemeter (Keithley 236) and a spectroradiometer (Konica Minolta, Cs-2000) that apply and measure voltage and current and measuring the intensity and spectrum of the emitted electroluminescence. Manufacturing Example 1 and Comparative Manufacturing Example 1 were analyzed as described above, and the results are shown in FIG. 16B.

Referring to FIG. 16B, it can be seen that the luminance according to the current density of Manufacturing Example 1 was superior to that of Comparative Manufacturing Example 1.

### Experimental Example 15: External Quantum Efficiency-Voltage Analysis of Light-Emitting Devices

The external quantum efficiency-voltage graphs of light-emitting devices were analyzed by driving the electronic devices using a sourcemeter (Keithley 236) and a spectroradiometer (Konica Minolta, Cs-2000) that apply and measure voltage and current and measuring the intensity and spectrum of the emitted electroluminescence. Manufacturing Example 1 and Comparative Manufacturing Example 1 were analyzed as described above, and the results are shown in FIG. 16C.

Referring to FIG. 16C, it can be seen that the external quantum efficiency according to the voltage of Manufacturing Example 1 was far superior to that of Comparative Manufacturing Example 1.

### Experimental Example 16: Electroluminescence Spectrum of Light-Emitting Devices

The electroluminescence spectra of the light-emitting devices were analyzed by applying voltage using a spectroradiometer (Konica Minolta, Cs-2000) and measuring the emitted electroluminescence spectra. Manufacturing Example 1, Comparative Manufacturing Example 1, Comparative Manufacturing Example 2, Comparative Manufacturing Example 3, and Comparative Manufacturing Example 4 were analyzed as described above, and the results are shown in FIGS. 11C and 16D.

Referring to FIG. 16D, unlike Comparative Manufacturing Example 1, Manufacturing Example 1 exhibited an emission spectrum peak at 462 nm. This is because the average distance between nanocrystals in the emitters of Manufacturing Example 1 was sufficiently far, so that energy transfer and electronic coupling were suppressed and thus a red shift was prevented. Therefore, unlike Comparative Manufacturing Example 1, Manufacturing Example 1 may exhibit excellent emission of deep blue light.

Referring to FIG. 11C, it was confirmed that when the average distance between nanocrystals was increased by adding an organic host (CBP, DCzPPy, and TCTA), energy transfer and electronic coupling between nanocrystals were suppressed, thereby obtaining a deep blue electroluminescence spectrum. However, it can be seen that the emitters manufactured using the TCTA organic host exhibited undesirable exciplex emission in the green region because the HOMO energy level of TCTA is −5.83 eV. Therefore, the exciplex formation with the electron transport layer (CN-T2T) may be prevented only when the HOMO energy level of the organic host is below −6.0 eV.

### Experimental Example 15: Color Position Graphs of Electroluminescence Spectra of Light-Emitting Devices

The color position graphs of the electroluminescence spectra of the light-emitting devices were analyzed by applying voltage using a spectroradiometer (Konica Minolta, Cs-2000) and calculating the color positions of the emitted electroluminescence spectrum according to the CIE1931 color coordinates. Manufacturing Example 1 and Comparative Manufacturing Example 1 were analyzed as described above, and the results are shown in FIG. 16E.

With reference to FIG. 16E, it can be confirmed that Manufacturing Example 1 emitted more deep blue light compared to Comparative Manufacturing Example 1.

Although one embodiment of the present invention has been described above, the spirit of the present invention is not limited to the embodiment presented herein, and those skilled in the art who understand the spirit of the present invention will be able to easily suggest other embodiments by adding, changing, and deleting components within the scope of the same spirit, but this will also be considered to fall within the scope of the spirit of the present invention.

What is claimed is:

1. Halide perovskite nanocrystal particles comprising a halide perovskite nanocrystal, wherein an acyl halide of Chemical Formula 1 below is bonded to the surface of the perovskite nanocrystal: 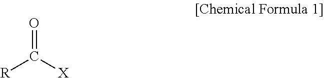
in Chemical Formula 1, X is a halogen element corresponding to F, Cl, Br, or I, and R is a substituted or unsubstituted aromatic ring or a substituted or unsubstituted hydrocarbon group.

2. The halide perovskite nanocrystal particles of claim 1, wherein the perovskite nanocrystal is surrounded by organic or inorganic ligands.

3. The halide perovskite nanocrystal particles of claim 1, wherein the acyl halide of Chemical Formula 1 is selected from the group consisting of acetyl bromide, propionyl bromide, valeryl bromide, benzoyl bromide, bromoacetyl bromide, 2-bromopropionyl bromide, 2-bromobutyryl bromide, acetyl chloride, propionyl chloride, valeryl chloride, benzoyl chloride, isovaleryl chloride, 3-chloropropionyl chloride, 2-chloropropionyl chloride, acetyl iodide, propionyl iodide, valeryl iodide, benzoyl iodide, bromoacetyl iodide, 2-bromopropionyl iodide, and 2-bromobutyryl iodide.

4. The halide perovskite nanocrystal particles of claim 1, wherein the halide perovskite nanocrystal includes an ABX3 crystal, A is a monovalent organic cation, a monovalent inorganic cation, or a combination thereof, B is a divalent metal ion, and X is F, Cl, Br, I, SCN, OCN, SeCN—, HCO2—, CH3COO⁻, or a combination thereof.

5. The halide perovskite nanocrystal particles of claim 1, wherein a size of the halide perovskite nanocrystal ranges from 3 nm to 30 nm.

6. The halide perovskite nanocrystal particles of claim 1, wherein the size of the halide perovskite nanocrystal is 3 to 5.5 nm, and the halide perovskite nanocrystal has an emission spectrum peak at a wavelength of 440 to 470 nm.

7. Halide perovskite nanocrystal particle emitters comprising:
the halide perovskite nanocrystal particles of claim 1; and
an organic host.

8. The halide perovskite nanocrystal particle emitters of claim 7, wherein the organic host prevents a red shift by suppressing energy transfer and electronic coupling between halide perovskite nanocrystals.

9. The halide perovskite nanocrystal particle emitters of claim 7, wherein the organic host has a highest occupied molecular orbital (HOMO) energy level of −6.0 eV or less.

10. The halide perovskite nanocrystal particle emitters of claim 7, wherein the organic host is a carbazole derivative.

11. The halide perovskite nanocrystal particle emitters of claim 7, wherein the organic host is selected from the group consisting of Chemical Formulas 2 to 4:

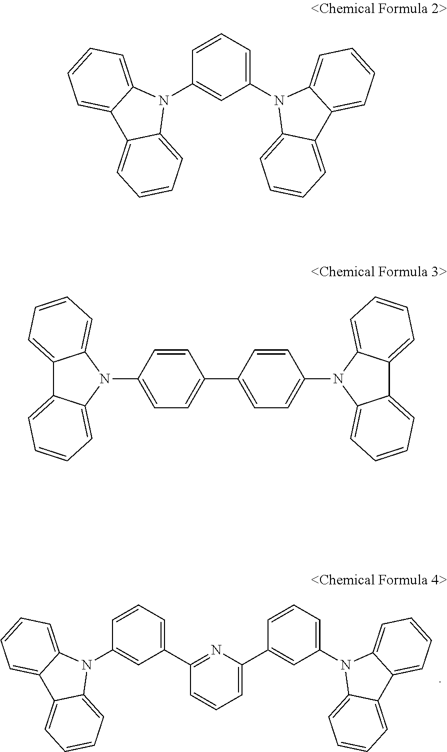 [SMILES: c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-c3cccc(-n4c5ccccc5c5ccccc54)c3)n2)cc(-n2c3ccccc3c3ccccc32)c1]

12. The halide perovskite nanocrystal particle emitters of claim 7, wherein 1 to 60 parts by weight of the nanocrystal is mixed based on 100 parts by weight of the organic host.

13. A method of manufacturing halide perovskite nanocrystal particle emitters, comprising:
preparing a halide perovskite nanocrystal particle solution or thin film; and
performing surface treatment or ligand substitution on a halide perovskite nanocrystal using an additive solution containing an acyl halide represented by Chemical Formula 1 below in the halide perovskite nanocrystal particle solution or thin film: 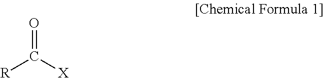
in Chemical Formula 1, X is a halogen element corresponding to F, Cl, Br, or I, and R is a substituted or unsubstituted aromatic ring or a substituted or unsubstituted hydrocarbon group.

14. The method of claim 13, wherein the additive solution further includes a ligand.

15. The method of claim 14, wherein the ligand is selected from the group consisting of aniline, benzylamine, phenethylamine, 3-phenyl-1-propylamine, 4-phenylbutylamine, ethylamine, propylamine, butylamine, pentylamine, isobutylamine, and isopropylamine.

16. The method of claim 14, wherein the additive solution is a solution containing 0.01 to 50 parts by weight of the acyl halide and ligand based on 100 parts by weight of a nonpolar solvent.

17. The method of claim 13, further comprising additionally forming a passivation layer on an upper portion or lower portion of the thin film using the additive solution containing the acyl halide.

18. The method of claim 13, wherein the halide perovskite nanocrystal particle emitters further include an organic host.
